(19) United States
(12) Patent Application Publication
(10) Pub. No.: US 2021/0348274 A1
(43) Pub. Date: Nov. 11, 2021

(54) PLASMA ENHANCED ATOMIC LAYER DEPOSITION (PEALD) APPARATUS

(71) Applicant: Evatec AG, Trübbach (CH)

(72) Inventors: Jörg PATSCHEIDER, Meilen (CH); Hartmut ROHRMANN, Schriesheim (DE); Jürgen WEICHART, Balzers (LI); Florian BRITT, Heiligkreuz (CH)

(21) Appl. No.: 17/282,014

(22) PCT Filed: Sep. 23, 2019
(86) PCT No.: PCT/EP2019/075566

§ 371 Date: Apr. 1, 2021

(30) Foreign Application Priority Data
Oct. 2, 2018 (CH) 01205/18
Dec. 24, 2018 (CH) 01602/18

(51) Int. Cl. C23C 16/455; C23C 16/40; C23C 16/507; H01J 37/32

(52) U.S. Cl. CPC C23C 16/45542; C23C 16/403; C23C 16/45544; H01J 37/32678; H01J 37/32449; C23C 16/507

(57) ABSTRACT

Within a vacuum recipient plasma enhanced atomic layer deposition (PEALD) is performed in that precursor gas is inlet from a precursor gas inlet and a monomolecular layer is deposited on a substrate by adsorption. Subsequently a reactive gas is inlet through a reactive gas inlet and the monomolecular layer on the substrate is reacted, enhanced by UHF plasma which is generated to be distributed along a geometric locus which surrounds a substrate carrier and thus the substrate on this carrier.

The present invention is directed to a plasma enhanced atomic layer deposition (PEALD) apparatus and to a method of manufacturing a device comprising a substrate and a layer deposited thereon by PEALD. By atomic layer deposition a molecular layer is deposited by adsorption.

Large scale, industrial layer deposition on three-dimensionally structured very small (down to sub-nm) structures is a highly demanding object.

This object is resolved according to the present invention by a plasma enhanced atomic layer deposition (PEALD) apparatus, which comprises:
a vacuum recipient;
at least one controllable pumping port from the vacuum recipient;
at least one controllable plasma source communicating with the inner of the recipient;
at least one controllable precursor gas inlet to the inner of said recipient;
at least one controllable reactive gas inlet to the inner of said recipient;
a substrate carrier in said recipient.

The at least one plasma source is a UHF plasma source and is constructed to generate, distributed along a locus all around the periphery of the substrate carrier, a plasma in the vacuum recipient.

The apparatus according to the invention provides for short PEALD overall processing time and thus high throughput. This is primarily due to the fact that the apparatus is constructed to perform all PEALD steps in one common vacuum recipient and provides highly efficient oxidation.

So as to fully understand the following explanation, we give a short overview of the PEALD deposition method according to the invention.

The surface of the substrate to be treated is normally first pretreated i.e. reacted with at least one reactive gas which may contain, as examples, at least one of the elements oxygen, nitrogen, carbon. Thereby optimum deposition conditions are created for the subsequent molecular layer deposition (ALD). This initial step—in fact to provide optimum starting conditions for the subsequent ALD deposition—is significantly improved and shortened as well by performing it in a plasma-enhanced manner, thus by the addressed controllable plasma source as well.

After stopping reactive gas feed and disabling the controllable plasma source, then pumping the vacuum recipient, precursor gas containing a metal is fed to the vacuum recipient and a mono-molecular layer of the metal-containing precursor adsorbs on the pre-treated surface of the substrate in a self-limiting manner. The adsorption stops, as soon as the respective surface is saturated with adsorbed molecules.

After pumping the remaining precursor gas from the vacuum recipient, the resulting metal-containing surface is reacted making use of a reactive gas containing e.g. at least one of the elements oxygen, nitrogen, carbon, hydrogen and enhanced by the plasma of the addressed plasma source.

The steps of molecule-layer deposition by adsorption and of subsequent reacting may be repeated in the vacuum recipient more than once. Thereby repeated reacting steps, and/or the initial reacting step, if at all performed, may use equal or different reactive gases. Thus, the apparatus may comprise more than one controllable reactive gas inlet.

In analogy, if multiple molecular layers are to be deposited, this may be done with different precursor gases. Thus, the apparatus may comprise more than one controllable precursor gas inlet.

### Definition

We understand throughout the present description and claims under UHF (ultra-high frequencies) frequencies f, for which there is valid:

0.3 GHz≤f≤3 GHz.

### Definition

We understand throughout the present description and claims under a “substrate” to be held by or on the substrate carrier of the PEALD apparatus, one or more than one distinct workpiece. The entirety of such workpieces simultaneously PEALD-treated are named “substrate”. Irrespective whether the substrate consists of a single workpiece or of more than one workpiece, once held on the substrate carrier, it or they commonly define for an extended overall surface of such substrate, which is exposed to PEALD treatment and thus exposed to a treatment space in the vacuum recipient.

In one embodiment of the apparatus according to the invention, the controllable plasma source is an Electron Cyclotron Resonance (ECR) source. This additionally improves efficiency of the one or more than one reacting steps.

In one embodiment of the apparatus according to the invention, the plasma source comprises a multitude of UHF power sources each directly UHF-coupled to the inner space of the vacuum recipient via a respective coupling area e.g. through the wall of the vacuum recipient. Thus, in fact, one plasma source is directly coupled through a coupling area at a distinct position to the inner space of the vacuum recipient per equal unit of the circumferential extent of the substrate carrier, whereby, for an ECR plasm source, an ECR permanent-magnet arrangement is distributed all-along the addressed locus.

In one embodiment of the apparatus according to the invention, the coupling area comprises a fused silica window sealing the inside of the vacuum recipient with respect to the UHF power source.

In one embodiment of the apparatus according to the invention the plasma source comprises a waveguide arrangement distributed all along the locus and comprises one or a multitude of coupling areas into the vacuum recipient, distributed all along the periphery of the substrate and further comprises at least one UHF power input.

Thereby a homogeneous distribution of the reaction effect along the respective surface of the substrate is achieved.

In one embodiment of the apparatus according to the invention, a substrate on the substrate carrier has an extended surface to be PEALD-coated exposed to a treatment space in the vacuum recipient, the addressed locus being located around the treatment space. It is in this space, that the at least one controllable reactive gas inlet as well as the at least one controllable precursor gas inlet are provided and to which the surface of the substrate on the substrate carrier is exposed for PEALD.

In one embodiment of the apparatus according to the invention, the waveguide arrangement comprises more than one distinct waive guide segments, each comprising at least one UHF power input. Thereby the distribution of the electromagnetic field along the substrate may be controlled.

In one embodiment of the apparatus according to the invention, the waveguide arrangement is formed by at least one hollow waveguide, and at least some of the coupling areas comprise a slit in the at least one hollow waveguide. If the waveguide arrangement is formed by a single waveguide, these slits are distributed along this waveguide. If the waveguide arrangement comprises more than one distinct waveguide segment, one or more than one of the addressed slits is or are provided at each of the waveguide segments.

In one embodiment of the apparatus according to the invention the vacuum recipient has a center axis and comprises at least two of the addressed waveguide arrangements staggered in direction of the central axis.

In one embodiment of the just addressed embodiment of the apparatus according to the invention the at least one UHF power input of one of the at least two waveguide arrangements and the at least one power input of a further of the at least two waveguide arrangements are located mutually angularly displaced, seen in direction of the central axis. Thereby it becomes possible to homogenize the resulting plasma density along the locus all around the periphery of the substrate carrier.

In one embodiment of the just addressed embodiment of the apparatus according to the invention the substrate carrier defines a substrate plane, along which a substrate on the substrate carrier extends, and comprises at least two of the addressed waveguide arrangements staggered in a direction perpendicular to the substrate plane.

In one embodiment of the just addressed embodiment of the apparatus according to the invention the at least one UHF power input of one of the at least two waveguide arrangements and the at least one power input of a further of the at least two waveguide arrangements are located mutually angularly displaced, seen in direction towards the substrate plane.

In one embodiment of the apparatus according to the invention, the vacuum recipient has a center axis, at least some of the slits define respective slit-opening surfaces, the central normals thereon pointing towards the central axis. Seen from the treatment space towards the substrate carrier in treatment position, the inner wall of the vacuum recipient commonly extends along a circle locus, an elliptic locus, a polygonal locus, thereby especially a square or a quadratic locus. Thus, a center axis is well defined. The substrate carrier defines for a substrate plane, along which a substrate on the substrate carrier extends. The substrate carrier is customarily and in treatment position centered with respect to the center axis, and the substrate plane is perpendicular to the addressed center axis.

Therefore, in one embodiment of the apparatus according to the invention, the substrate carrier defines a substrate plane, along which a substrate on the substrate carrier extends, and the center axis is perpendicular to the substrate plane.

In one embodiment of the apparatus according to the invention, the substrate carrier defines a substrate plane, along which a substrate on the substrate carrier extends. At least some of the slits as addressed define respective slit-opening surfaces, the central normals thereon being parallel to the substrate plane.

In one embodiment of the apparatus according to the invention, the cross-sectional areas of hollow waveguides of the waveguide arrangement have symmetry planes or a common symmetry plane, perpendicular to the center axis and/or parallel to the substrate plane and at least some of the slits are offset from the symmetry planes or from the common symmetry plane.

In one embodiment of the just addressed embodiment of the apparatus according to the invention, some of the addressed slits are offset from the respective symmetry plane or from the common symmetry plane to one side, others of said slits to the other side.

In one embodiment of the apparatus according to the invention, the just addressed slits are alternatingly offset to one and to the other side of the respective symmetry plane or of the common symmetry plane.

In one embodiment of the apparatus according to the invention, the waveguide arrangement comprises or consists of hollow waveguides having a rectangular inside cross-section.

In one embodiment of the apparatus according to the invention, the waveguide arrangement comprises or consists of hollow waveguides, and the interior of the hollow waveguides is vacuum-sealed with respect to the interior of the vacuum recipient.

In one embodiment of the apparatus according to the invention, the addressed slits are vacuum-sealed with respect to the interior of the vacuum recipient.

In one embodiment of the apparatus according to the invention, the slits are vacuum-sealed with respect to the interior of the vacuum recipient by fused silica windows.

In one embodiment of the apparatus according to the invention, the UHF plasma source is a 2.45 GHz plasma source.

In one embodiment of the apparatus according to the invention, the waveguide arrangement comprises or consists of linearly extending waveguide sections.

In one embodiment of the apparatus according to the invention, the waveguide arrangement is located outside the vacuum recipient, and UHF communicates via coupling areas with the inside of the vacuum recipient.

In one embodiment of the apparatus according to the invention, the substrate carrier defines a substrate plane along which a substrate on the substrate carrier extends, the addressed locus extending along a plane parallel to the substrate plane.

In one embodiment of the apparatus according to the invention, the waveguide arrangement is removable from the vacuum recipient as one distinct part.

In one embodiment of the apparatus according to the invention, the plasma source is an ECR plasma source and comprises a permanent-magnet arrangement distributed all along the addressed locus.

In one embodiment of the apparatus according to the invention, the plasma source comprises a permanent-magnet arrangement adjacent to and along the waveguide arrangement.

In one embodiment of the apparatus according to the invention, the waveguide arrangement consists of or comprises at least one hollow waveguide. The permanent-magnet arrangement comprises an outer pole area of one magnetic polarity and an inner pole area of the other magnetic polarity. The outer pole area extends aligned with the hollow inner space of the at least one hollow waveguide, the inner pole area extends remote from the waveguide arrangement but adjacent to the coupling areas.

One embodiment of the apparatus according to the invention comprises a plasma ignitor arrangement, which comprises an ignitor flashlight.

In one embodiment of the apparatus according to the invention, the magnet arrangement is removable from the vacuum recipient as one distinct part.

One embodiment of the apparatus according to the invention comprises at least one precursor reservoir containing a precursor comprising a metal and operationally connected to the at least one controllable precursor gas inlet. If more than one precursor reservoirs are provided, respectively operationally connected to a respective controllable precursor gas inlet, these precursor reservoirs may contain different precursors.

In one embodiment of the apparatus according to the invention, the addressed metal is aluminum.

One embodiment of the apparatus according to the invention comprises at least one reactive gas tank operationally connected to the at least one controllable reactive gas inlet. If more than one reactive gas reservoirs are provided, respectively operationally connected to a respective controllable reactive gas inlet, these reactive gas reservoirs may contain different reactive gases.

In one embodiment of the apparatus according to the invention, the addressed reactive gas contains at least one of the elements oxygen, nitrogen, carbon, hydrogen.

In one embodiment of the apparatus according to the invention, the at least one precursor gas inlet discharges centrally with respect to a substrate on the substrate carrier in a treatment position and towards the substrate.

In one embodiment of the apparatus according to the invention, the at least one controllable precursor gas inlet and the at least one controllable reactive gas inlet discharge both centrally with respect to a substrate on the substrate carrier in a treatment position and towards the substrate.

In one embodiment of the apparatus according to the invention, the substrate carrier with a substrate thereon in a treatment position defines in the vacuum recipient a treatment compartment and wherein there is valid for a ratio Φ of the volume of the treatment compartment to a top-view surface area of the substrate to be PEALD-treated on the substrate carrier:

8 cm≤Φ≤80 cm

preferably

10 cm≤Φ≤20 cm.

Thus, as an example, if a structured or unstructured 200 mm wafer is to be treated, the top view surface area is 10²·πcm². A treatment compartment of 5 liters fulfills the condition cited above, in that the ratio Φ becomes

$$\frac{50}{π} cm \approx 15 cm .$$

Please note, that the addressed top view surface area on the extended surface of the substrate is not dependent from whether the addressed extended surface is three dimensionally structured, bent or flat. The volume of the treatment compartment relative to the substrate extent is very small, which improves pumping time spans, molecular layer adsorption time spans, reacting time spans, and saves precious precursor gas.

In one embodiment of the apparatus according to the invention, whenever a substrate on the substrate carrier is in a treatment position, a treatment compartment enclosing the treatment space in the vacuum recipient is separated from a pumping compartment in the vacuum recipient by a controllable pressure stage. The treatment compartment may be constructed with optimally small volume. Once reacting and, respectively, molecular layer adsorption is terminated, the pressure stage is removed or opened, and a fast pumping of the former treatment compartment may be established through wide open flow communication from the former treatment compartment to the pumping compartment and the at least one controlled pumping port therein. The pumping compartment may be constructed optimally large to accommodate at least one large controlled pumping port.

In one embodiment of the apparatus according to the invention, the pressure stage is a seal, in one embodiment a non-contact flow restriction. In the latter case any vibratory load of the substrate when establishing the pressure stage, as addressed, may be avoided.

In one embodiment of the apparatus according to the invention, the substrate carrier is controllably movable between a loading/unloading position and a PEALD treatment position.

One embodiment of the apparatus according to the invention comprises a controllably movable substrate handler arrangement operationally coupled to the substrate carrier.

One embodiment of the apparatus according to the invention comprises at least one substrate handling opening in the vacuum recipient.

One embodiment of the apparatus according to the invention comprises a bidirectional substrate handler cooperating with the at least one substrate handling opening.

One embodiment of the apparatus according to the invention comprises at least two substrate handling openings in the vacuum recipient, an input substrate handler cooperating with one of the at least two substrate handling openings and an output substrate handler cooperating with the other of the at least two substrate handling openings.

In one embodiment of the apparatus according to the invention, both the input substrate handler and the output substrate handler are realized commonly by a substrate conveyer. Such a substrate conveyer handles an untreated substrate trough one of the at least two substrate handling openings into the vacuum recipient—thus acting as input substrate handler—and simultaneously removes a yet treated substrate from the vacuum recipient through the second substrate handling opening, —thus acting as an output substrate handler.

In one embodiment of the apparatus according to the invention, a timing controller, as of a computer, also called timer unit, is operationally connected at least to a control valve arrangement to said at least one precursor gas inlet, to a control valve arrangement to said at least one reactive gas inlet, to said at least one plasma source, —so as to enable/disable the plasma source effect in the reaction space—and to the at least one controllable pumping port—to enable/disable the pumping effect to the vacuum recipient.

The timing control of the overall apparatus according to the invention is performed by the timing unit, e.g. to practice the method and its variants addressed below.

Any number of embodiments addressed of the apparatus according to the invention may be combined unless being in contradiction.

The invention is further directed to a method of manufacturing a substrate with a layer deposited thereon by PEALD, which comprises:
(0) providing a substrate in a recipient; Evacuating the recipient;
(1) feeding a precursor gas into the evacuated recipient and depositing by adsorption a molecular layer from a material in the precursor gas on the substrate;
(2) pumping remaining precursor gas from the recipient;
(3) igniting a plasma in the recipient and plasma-enhanced reacting the deposited molecular layer on the substrate with a reactive gas,
(4) pumping the recipient and
(5) removing the substrate from the recipient.

In one variant of the method according to the invention, the method is performed by means of an apparatus according to the invention or by means of at least one embodiment thereof.

In one variant of the method according to the invention, steps (1) to (4) are repeated at least once after step (0) and before step (5). Thereby more than one molecular layer is deposited and reacted.

In one variant of the method according to the invention, repeating of step (1) is performed by feeding different precursor gases during at least some of the repeated steps (1). Thus, at least some of the more than one molecular layers may be of different materials.

In one variant of the method according to the invention, repeating of step (3) is performed by feeding different reactive gases during at least some of the repeated steps (3). Thus, at least some of the adsorbed molecular layers may be differently reacted.

In one variant of the method according to the invention, at least some of the repeated steps (3) are performed without igniting a plasma.

One variant of the method according to the invention comprises performing a step (0a) after the step (0) and before the step (1), in which step (0a) the surface of the substrate is reacted with a reactive gas.

Molecular layer deposition (ALD) necessitates most often a pretreated deposition surface. This may be realized in that the substrate provided into the recipient according to step (0) provides already such pretreated i.e. reacted surface, as realized before feeding the substrate into the recipient, or is, according to the just addressed variant, realized in the evacuated recipient, after the substrate having been provided therein as an initial, pretreating step by reacting in a reactive gas atmosphere.

In one variant of the method according to the invention, a plasma is ignited in step (0a).

In one variant of the method according to the invention, the reactive gas in step (0a) is different from the reactive gas in at least one step (3).

In one variant of the method according to the invention, the reactive gas in step (0a) and the reactive gas in at least one step (3) are equal.

In one variant of the method according to the invention, the precursor gas in step (1) or in at least one of repeated steps (1) is TMA.

In one variant of the method according to the invention, the reactive gas or gases contain at least one of the elements oxygen, nitrogen, carbon, hydrogen.

In one variant of the method according to the invention said step (1) or at least one of repeated steps (1) is performed in a time span T₁ for which there is valid:

0.5 sec.≤T₁≤2 sec,

preferably

T₁≅1 sec.

In one variant of the method according to the invention, the step (2) or at least one of repeated steps (2) is performed in a time span T₂ for which there is valid:

0.5 sec.≤T₂≤2 sec,

preferably

T₂≅1 sec.

In one variant of the method according to the invention, step (3) or at least one of repeated steps (3) is performed in a time span T₃ for which there is valid:

0.5 sec.≤T₃≤2 sec,

preferably

T₃≅1 sec.

In one variant of the method according to the invention, the step (4) or at least one of repeated steps (4) is performed in a time span T₄ for which there is valid:

0.5 sec.≤T₄≤2 sec,

preferably

T₄±1 sec.

One variant of the method according to the invention comprises performing a step (0a) after the step (0) and before the step (1), in which step (0a) the surface of the substrate is reacted with a reactive gas, the step (0a) is thereby performed in a time span T₀ₐ for which there is valid:

0.5 sec.≤T₀ₐ≤2 sec,

preferably

T₀ₐ≅1 sec.

One variant of the method according to the invention comprises establishing a higher gas flow resistance from a treatment space to a pumping space in the vacuum recipient between step (0) and step (1) and/or between step (2) and step (3) and establishing a lower gas flow resistance from the treatment space to the pumping space between step (1) and step (2) and/or between step (3) and step (4).

One variant of the method according to the invention comprises generating the plasma ignited in the step (3) distributed along a locus all around the periphery of the substrate.

Any number of variants of the method according to the invention may be combined unless being in contradiction.

The invention is further directed to a method of manufacturing a device comprising a substrate with a layer deposited thereon by PEALD according to the method of the invention as was addressed or at least one variant thereof.

The different aspects of the invention and combinations thereof, as well as such aspects and combinations as today realized are listed in a summarizing manner at the end of the description and will be even better understood after having read the subsequent, more detailed description of examples.

The invention shall now be further exemplified, as far as necessary for the skilled artisan, with the help of figures.

The figures show:

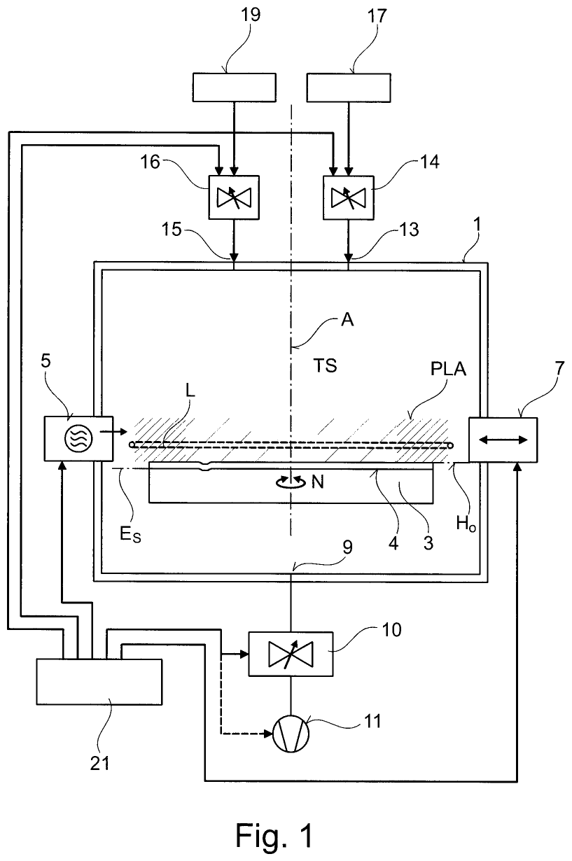

FIG. 1: schematically and in part in block-diagrammatic representation, the principal structure of an apparatus according to the invention, suited to operate the method according to the invention;

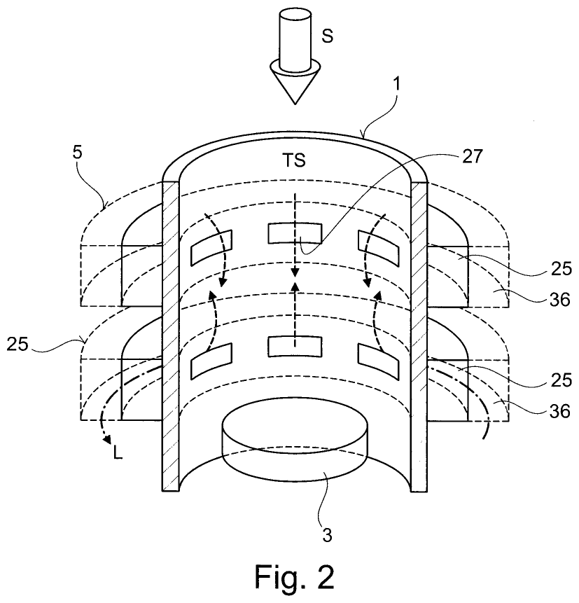

FIG. 2: schematically and simplified, and in a partly cut perspective representation, an embodiment of the plasma source in an embodiment of the apparatus according to the invention;

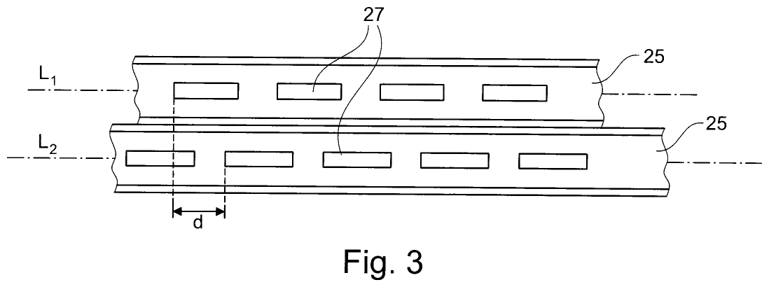

FIG. 3: schematically and simplified staggering coupling areas of multiple waveguides at the plasma source of embodiments of the apparatus according to the invention;

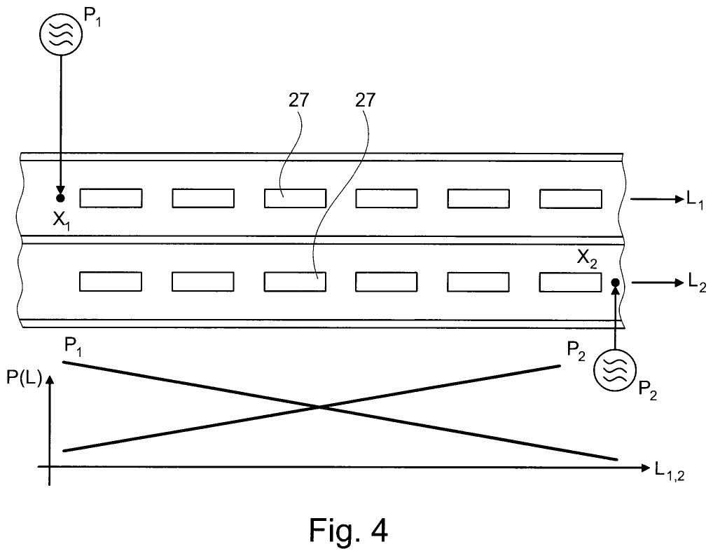

FIG. 4: schematically and simplified staggering UHF power supply locations of multiple waveguides at the plasma source of embodiments of the apparatus according to the invention;

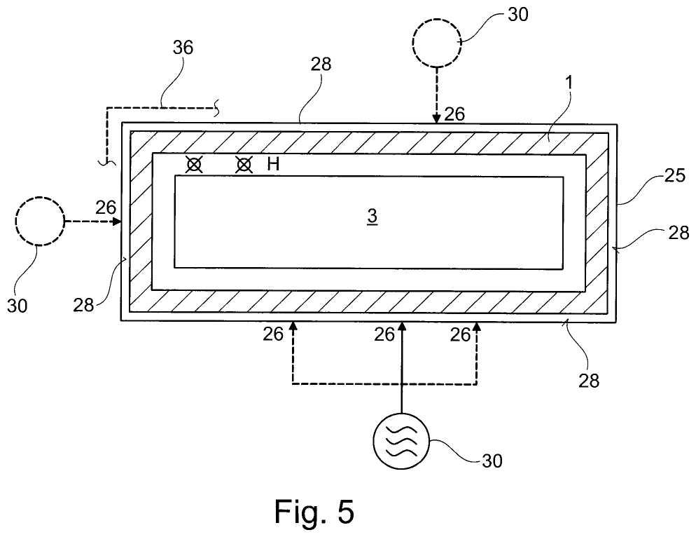

FIG. 5: in a schematic and simplified cross-sectional top view, a waveguide arrangement of embodiments of the apparatus of the invention;

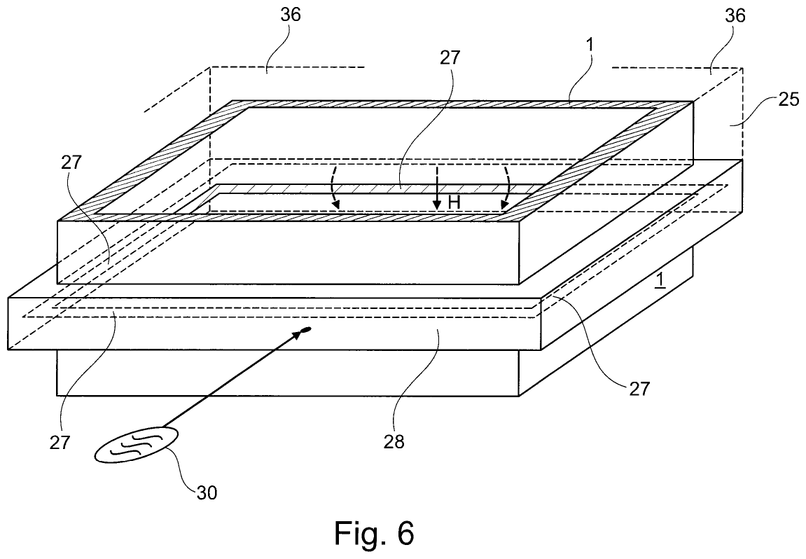

FIG. 6: in a perspective view the waveguide arrangement of the embodiment of FIG. 5 with single coupling area;

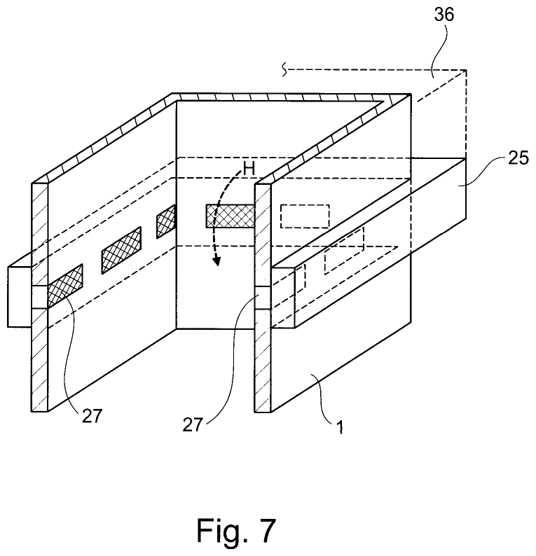

FIG. 7: schematically and simplified a part of the waveguide arrangement of the embodiment of FIGS. 4 and 5 with more than one coupling area;

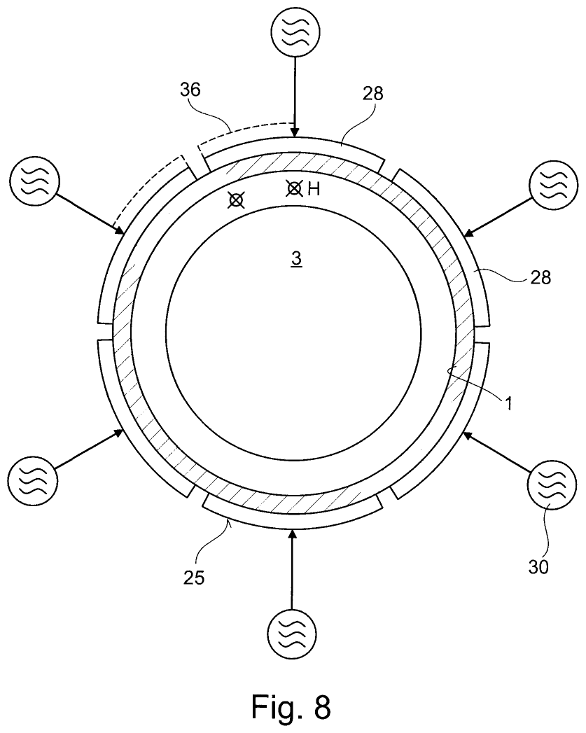

FIG. 8: a further realization form of a waveguide arrangement of further embodiments of the apparatus according to the invention.

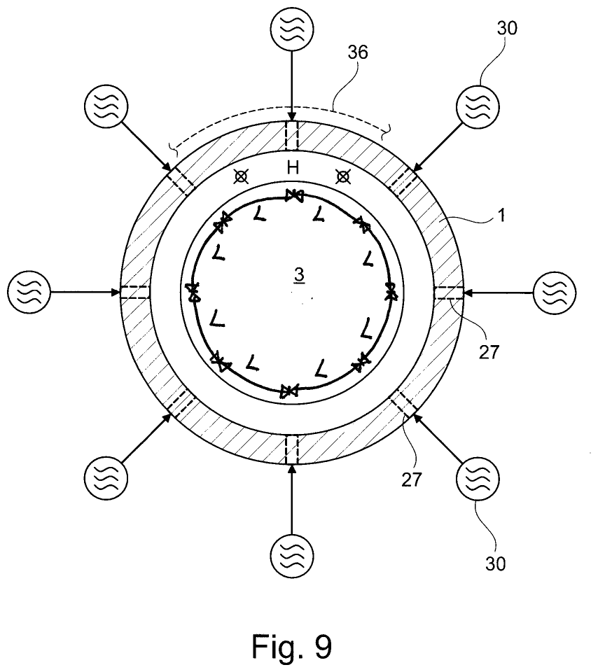

FIG. 9: schematically and simplified, in a representation in analogy to that of FIG. 8 UHF power feeding to the vacuum recipient in further embodiments of the apparatus according to the invention;

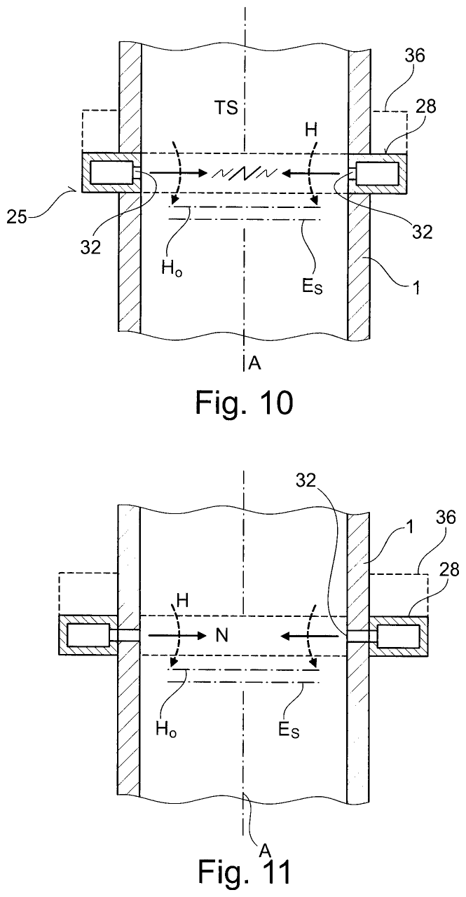

FIG. 10: schematically and simplified the realization of a waveguide arrangement including hollow wave guides in further embodiments of the apparatus according to the invention;

FIG. 11: in a representation in analogy to that of FIG. 10 the realization of a waveguide arrangement in further embodiments of the apparatus according to the invention;

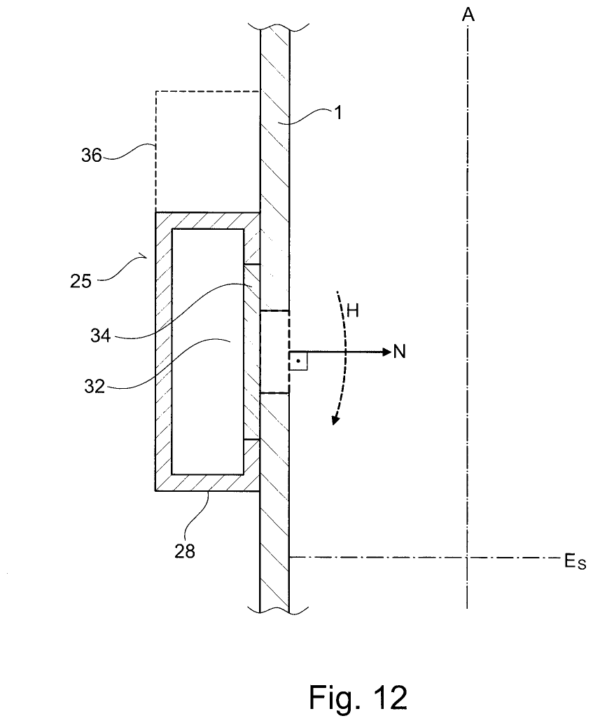

FIG. 12: simplified and schematically a cross section through a coupling area of further embodiments of the apparatus according to the invention;

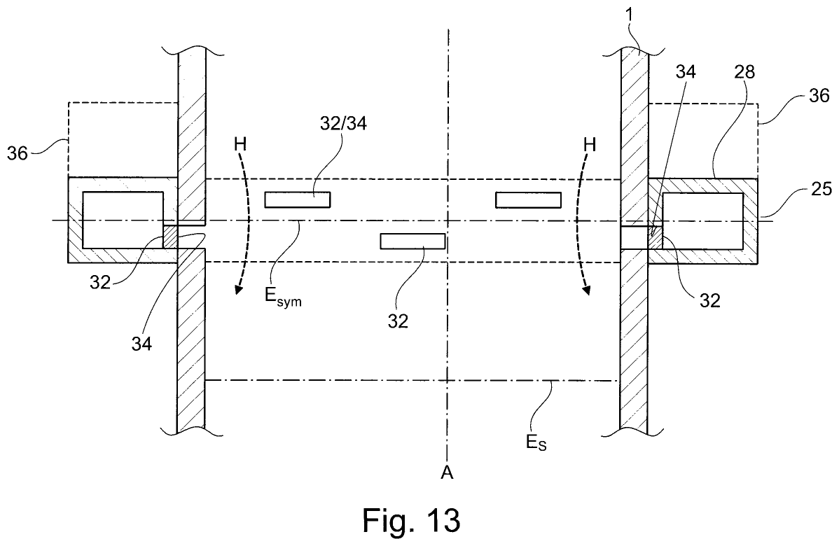

FIG. 13: simplified and schematically, the localization of coupling slits along the waveguide arrangement in embodiments of the apparatus according to the invention;

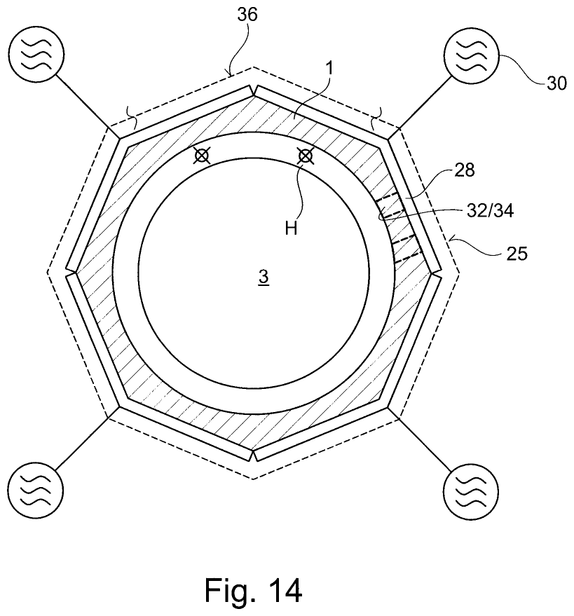

FIG. 14: in a top view, schematically and simplified the realization of a curved waveguide arrangement in embodiments of the apparatus according to the invention;

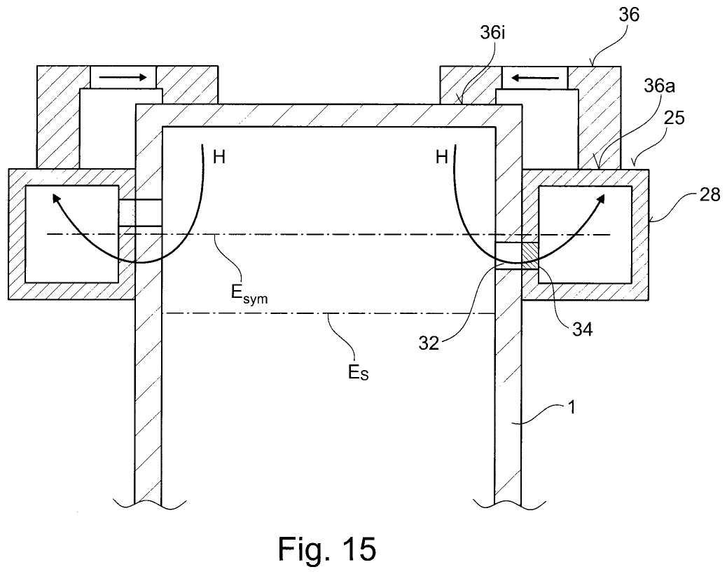

FIG. 15: schematically and simplified an ECR plasma source of embodiments of the apparatus according to the invention.

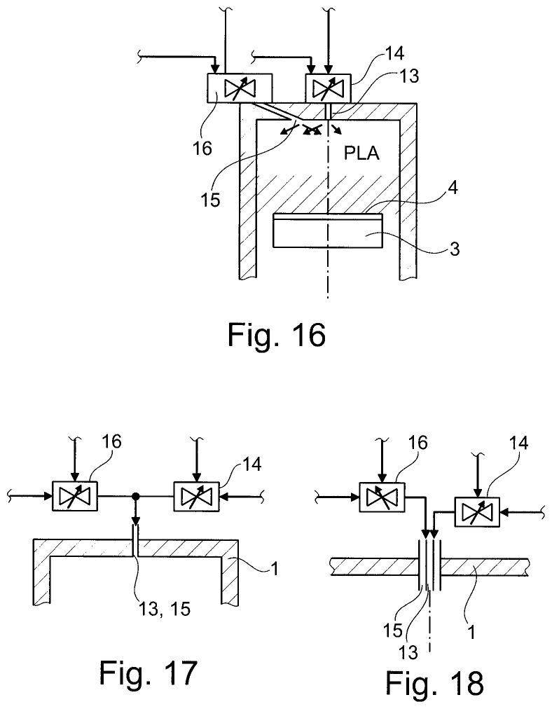

FIG. 16: schematically and simplified a precursor gas and reactive gas inlet arrangement at embodiments of the apparatus according to the invention;

FIGS. 17 and 18: schematically and simplified, further precursor gas and reactive gas inlet arrangements at embodiments of the apparatus according to the invention;

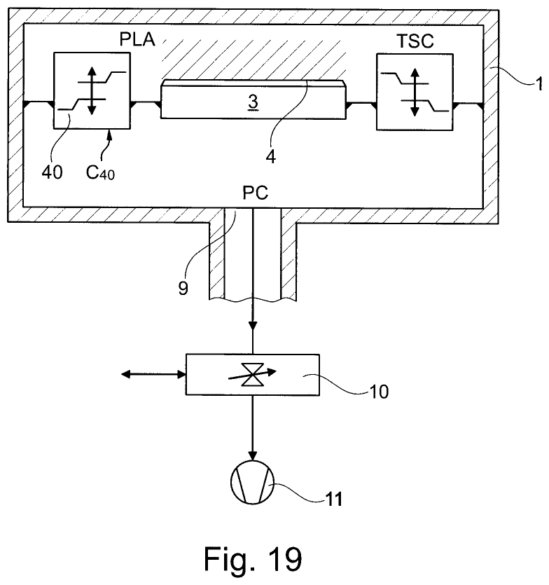

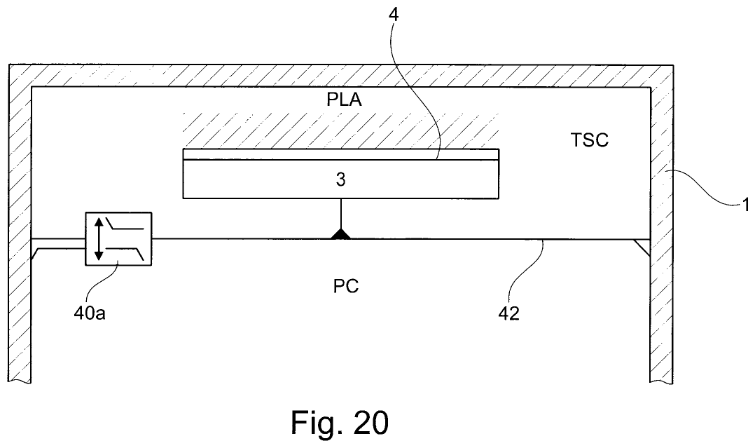

FIGS. 19 and 20: most simplified, generic and schematically, controlled separation of a treatment space from a pumping space in embodiments of the apparatus according to the invention;

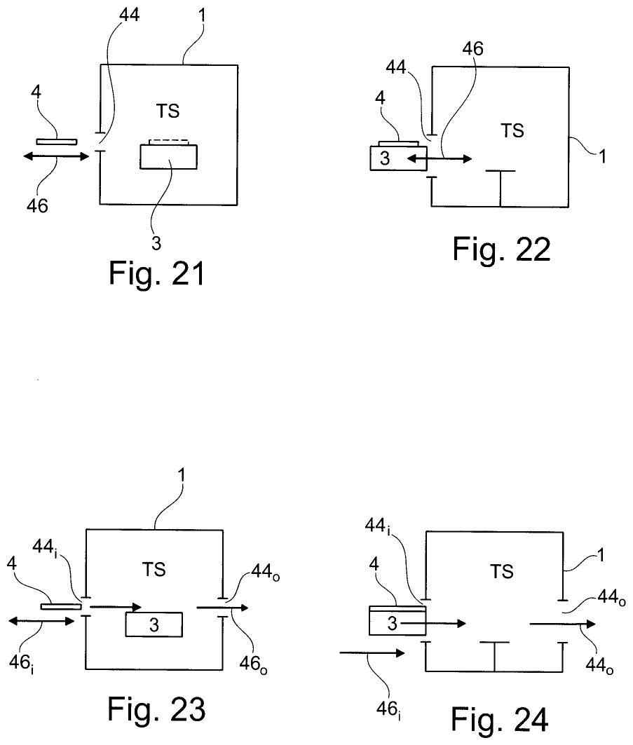

FIGS. 21 to 25: most schematically and simplified substrate handler arrangements which may be provided at embodiments of the apparatus according to the invention.

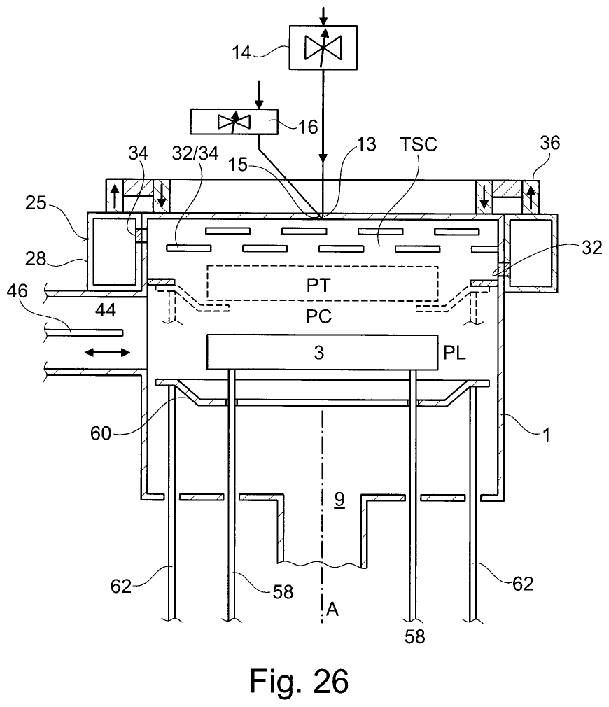

FIG. 26: schematically and simplified an embodiment of an apparatus according to the invention, combining embodiments as were addressed.

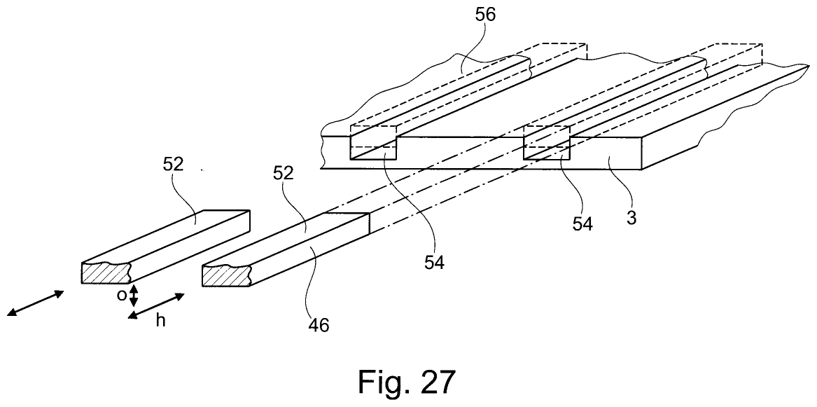

FIG. 27: schematically and simplified in a perspective representation, the cooperation of the substrate handler and the substrate carrier in an embodiment of the apparatus according to the invention, e.g. the embodiment of FIG. 26;

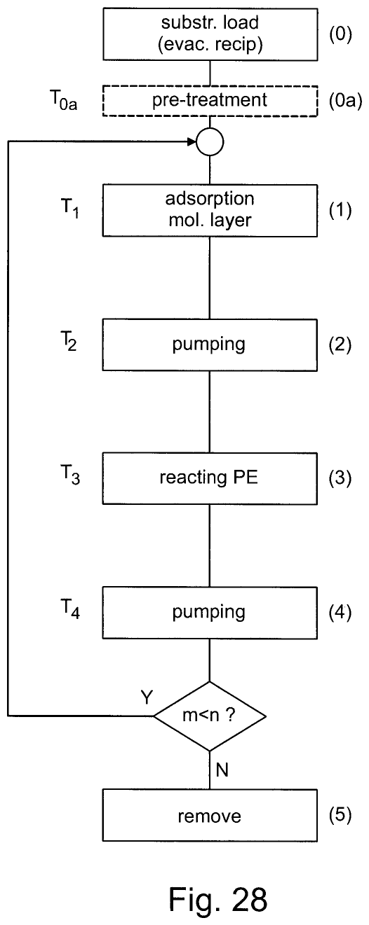

FIG. 28: a flow chart of the method according to the invention and as may be performed by the apparatus according to the invention.

According to FIG. 1 the apparatus according to the invention comprises a vacuum recipient 1. Within the vacuum recipient 1 a substrate carrier 3 holds, at least during PEALD treatment, a substrate 4 in a treatment position, with its surface to be PEALD-treated exposed to a treatment space TS in the vacuum recipient 1. A UHF-plasma source 5 is in operational connection with the inner space of the vacuum recipient 1 and is constructed to generate in the treatment space TS a plasma PLA distributed all along a locus L, schematically shown in dash line, extending all along the periphery of the substrate carrier 3, i.e. along the periphery of a substrate 4 to be PEALD-treated on the substrate carrier 3, as is schematically represented in FIG. 1.

The plasma PLA needs not necessarily be of homogeneous plasma density all along the locus L but may also be of varying density all along the locus L. e.g. of periodically varying density. So as to improve homogeneity of the plasma effect on the substrate 4 one might even rotate the substrate 4, as schematically shown at W.

The substrate is handled to and from the treatment position, with or without the substrate carrier 3, by means of a controllable substrate handler arrangement 7 through respective one or more than one handling openings (not shown in FIG. 1) in the wall of the vacuum recipient 1.

A controllable pumping port 9 to the vacuum recipient 1 is controlled by a control valve arrangement 10 or by direct control of a pumping arrangement 11 to which the controllable pumping port 9 is operationally connected.

A controllable precursor gas inlet 13, controllable by a controllable valve arrangement 14, and a controllable reactive gas inlet 15, controllable by a controllable valve arrangement 16, discharge in the treatment space TS of the vacuum recipient 1 and are respectively connectable to a precursor reservoir arrangement 17 and to a reactive gas tank arrangement 19.

A timer unit 21, e.g. a computer, controls timing of pumping the vacuum recipient 1, via controllable pumping port 9, operation of the plasma source 5, precursor gas flow, via controllable precursor gas inlet 13, reactive gas flow, via controllable reactive gas inlet 15, substrate handling via controllable substrate handler arrangement 7 in cooperation with the substrate carrier 3.

FIG. 2 shows, schematically and simplified, and in a partly cut perspective representation, a cylindrical vacuum recipient 1. The plasma source 5 comprises one or, as shown, more than one waveguide arrangement 25 looping around the periphery of the substrate carrier 3, as exemplified, along the outer surface of the vacuum recipient 1. Each of the waveguide arrangement 25 comprises one coupling area looping along the vacuum recipient 1, or as shown in FIG. 2, a multitude of coupling areas 27 distributed along the respective loops 25. At the coupling areas 27 UHF power is coupled from the one or more than one waveguide arrangement loops 25 into the treatment TS of the vacuum recipient.

The vacuum recipient 1 may have an internal cross-sectional shape extending along a circular, an elliptical, a polygonal, thereby especially a square or a quadratic locus. Accordingly, is the shape of the one or more than one loops of waveguide arrangement 25, seen from the top of the vacuum recipient 1, in direction S of FIG. 2. Each of the loops of waveguide arrangement 25 is fed by at least one UHF power source (not shown in FIG. 2).

The loci of the coupling areas 27 along the extent L of the waveguide arrangement 25 may cause inhomogeneous distribution of plasma density along the locus L. If two or more than two waveguide arrangements 25 are provided, each distributed along the respective locus L the coupling areas 27 of the waveguide arrangements 25 may be mutually displaced along the loci L as seen in direction S of FIG. 2. This is schematically represented in FIG. 3 by the displacements d of equally shaped coupling areas.

Whenever a waveguide arrangement 25 is UHF power supplied at an area X along the locus L, the power coupled into the vacuum recipient 1 diminishes from subsequent coupling area 27 to subsequent coupling area 27 along the locus L. If two or more than two waveguide arrangements 25 are provided, each distributed along the respective locus L, the areas X1 and X2 at which UHF power is supplied to the respective waveguide arrangements 25 may be mutually displaced along the loci L as seen in direction S of FIG. 2 and as addressed by D in the schematic representation of FIG. 4. In FIG. 4 the trend of UHF power P1 and P2 delivered to the vacuum recipient 1 by respective ones of the waveguide arrangements 25 along the extent of the locus L is qualitatively shown. As may be seen, attenuation of the UHF power coupled into the vacuum recipient 1 from one waveguide arrangement 25 is compensated by the UHF power from the other waveguide arrangement 25.

Thus, by adjusting or selecting the mutual displacement d of the coupling areas 27 and/or of the UHF power supply areas X, -D-, of at least two waveguide arrangements 25 placed one on the other along the vacuum recipient 1, the homogeneity of the plasma density along the locus L may be optimized. Please note, that if at least one of the waveguide arrangements 25 e.g. of FIG. 2, is constructed according to the embodiment of FIG. 10, it becomes possible to adjust the mutual position of the coupling areas and/or of the UHF supply areas by relative adjusting displacement merely of the two waveguide arrangements 25.

FIG. 5 shows in a schematic and simplified cross-sectional top view, a waveguide arrangement 25, which comprises a single looping waveguide 28, as an example along a rectangular-cross-section vacuum recipient 1. The waveguide 28 is fed by a UHF power source 30. As shown by dashed lines, more than one UHF power source 30 may be feeding the one waveguide 28 and/or one or more than one UHF power source may feed the waveguide 28 at different feeding areas or locations 26.

As schematically shown in FIG. 6 the coupling area 27 may be realized by a single, looping coupling area or, as shown in FIG. 7, by more than one, e.g. by a multitude of coupling areas distributed along the extent of the waveguide arrangement 25.

FIG. 8 shows a further realization form of the waveguide arrangement 25 of a further embodiment of the apparatus according to the invention. Here the waveguide arrangement 25 comprises more than one distinct waveguide 28, each being fed by at least one UHF power source 30.

Thereby, each single wave guide 28 may be UHF-coupled to the interior of the vacuum recipient 1 by a single continuous coupling area, in analogy to the coupling area 27 of the embodiment according to FIG. 6 or may be UHF-coupled by more than one coupling areas 27, in analogy to FIG. 7, to the interior of vacuum recipient 1, in fact to the treating space TS therein. Also, in this embodiment more than one UHF power source 30 may be connected to some or to all the waveguides 28 and/or one UHF power source 30 may be connected to more than one of the waveguides 28 and/or one UHF-power source 30 may be connected to one of the waveguides 28 at different feeding locations 26. In an extreme of the embodiment according to FIG. 8, the extent of the discrete waveguides 28 is reduced practically to zero and the UHF power is directly coupled to the treatment space TS of the vacuum recipient by multiple UHF power sources 30. Such an embodiment is schematically shown in FIG. 9. The coupling areas through the wall of the vacuum recipient 1 are schematically shown in FIG. 9 at reference number 27.

Thus, according to this embodiment no waveguide 28 is provided. The UHF plasma power sources are evenly distributed with respect to the substrate carrier 3, i.e. there is provided the periphery of one plasma power source 30 per equal unit L of circumferential extent of the substrate carrier 3.

If the circumferential extent is of the substrate carrier 3 is equal to the addressed unit L then only one UHF power source 30 is to be provided.

The unit L is thereby selected to be at least 40 cm or at least 50 cm or at least 60 cm or even at least 100 cm. The larger that the unit L may be selected the less UHF power sources are to be provided for a given extent of the circumferential extent of the substrate carrier. Please note, that the permanent magnet arrangement 36 which will be addressed later, extends or is distributed—if provided—all along the periphery of the substrate carrier 3, i.e. all along the locus along which the plasma is to be generated. By means of providing such permanent magnet arrangement 36, the plasma source or the plasma sources become Electron Cyclotron Resonance (ECR)-UHF plasma source or—sources.

The coupling area or areas 27 may thereby be output areas of UHF horn antennas.

In view of the required UHF power to be coupled into the treatment space TS of the vacuum recipient 1 and the UHF power to be applied, the one or more than one waveguide arrangement 25 as was/were addressed are mostly realized as hollow waveguides 28, as schematically shown in FIG. 10. All embodiments as of FIGS. 2 to 9 may be realized with the respective waveguide arrangement 25 comprising or consisting of hollow waveguides 28. The one or more than one coupling areas 27 comprise respectively one or more than one coupling slits 32 in the wall of the one or more than one hollow waveguide 28. As will be addressed later, these slits are covered with low-loss dielectric windows, esp. of fused silica and sealed e.g. by O-rings if the hollow waveguide(s) 28 is/are to be operated on an internal pressure different from the vacuum in the vacuum recipient 1.

In the embodiment of FIG. 10 the one or more than one waveguides 28 form a part of the wall of the vacuum recipient 1. Thereby the coupling areas, specifically the slits 32, do not traverse the wall of the vacuum recipient 1. Looking back on FIG. 2, this allows to mutually displace multiple waveguide arrangements 25 without considering coupling areas 27, specifically slits 32, provided through the wall of the vacuum recipient 1.

To avoid PEALD deposition on the surfaces of the waveguide 28 exposed to the treatment space TS these surfaces may be covered by a noble metal covering, as of gold.

Such a covering may, more generically, be applied in the apparatus according to the invention to all surfaces exposed to PEALD treatment but which should not be PEALD-coated.

FIG. 11 shows in a representation in analogy to that of FIG. 10, an embodiment in which the hollow waveguide is not exposed to PEALD treatment and the one or more than one coupling slits 32 transit the wall of the waveguide 28, as well as the wall of the vacuum recipient 1.

Please note that in the FIGS. 10 and 11 the point dotted line 4o indicates the location of the extended surface to be PEALD-treated of a substrate 4 on the substrate carrier 3, limiting the treatment space TS in the vacuum recipient 1.

In most cases the vacuum recipient 1 is, in top view according to the direction S of FIG. 2, constructed so that the inner space is limited by a wall, which extends along a circle, an ellipse, a polygon, thereby especially a square or a quadrat. In all these cases, the vacuum recipient has a center axis A.

Further, the substrate carrier 3 customarily defines a substrate plane, along which a substrate on the substrate carrier 1 extends. Such substrate plane Eₛ is shown in FIG. 1. Most often, the substrate plane Eₛ extends perpendicularly to the center axis A.

The coupling areas 27 and thereby also the one or more than one slits 32 are, in todays realized embodiments, spatially oriented so, that normals N in the center of and on the slit openings are radially directed towards the axis A and/or are parallel to the substrate surface Eₛ. This is schematically shown in FIGS. 10 and 11.

As further shown in FIG. 12 the one or more than one coupling slits 32 from the one or more than one hollow waveguide 28 to the treatment space TS in the vacuum recipient 1 are sealingly closed by dielectric material seals 34, e.g. of fused silica. This allows to operate the waveguide 28 in ambient atmosphere, whereas the treatment space TS is operated on the different conditions for PEALD.

As exemplified schematically in FIG. 13 the cross-sectional areas of the hollow waveguides 28—be it of circular or of square cross-sectional waveguides as shown in FIG. 13—have symmetry planes E_{sym} or a common symmetry plane, perpendicular to the center axis A and/or parallel to the substrate plane Eₛ. The at least one slit 32 or at least some of more than one slits 32 are offset from the symmetry planes E_{sym} or from a common symmetry plane.

As further exemplified in FIG. 13, at least some of the more than one slits 32 are offset from the symmetry planes E_{sym} or from a common symmetry plane to one side, others of the slits 32 to the other side.

A common symmetry plane E_{sym} is present, if the waveguides 28 of the waveguide arrangement 25 extend along a single plane perpendicular to the center axis A and/or parallel to the substrate plane Eₛ. More than one symmetry planes E_{sym} are present, if the waveguides 28 of the waveguide arrangement 25 extend respectively along different planes perpendicular to the center axis A and/or parallel to the substrate plane Eₛ.

Further and as also exemplified in FIG. 13, the slits 32 are alternatingly offset to one and to the other side of the respective symmetry planes E_{sym} or of the common symmetry plane.

As was addressed, the slits 32 are sealingly closed by dielectric material seals 34 as of fused silica.

As schematically shown in FIG. 14, whenever the cross-sectional shape of the vacuum recipient 1 is curved, e.g. circular, instead of realizing the waveguide arrangement 25 by means of respectively bent waveguides 28, especially hollow waveguides, the waveguide arrangement 25 may be realized by approximating the curved shape by means of linearly extending waveguides 28. Thereby and as shown in FIG. 14, some of the linear waveguides 28 may be interconnected and some may be separate in analogy to the embodiment of FIG. 8 resulting, in the embodiment of FIG. 14, in four distinct waveguides 28, each formed by two linear, joint waveguide parts. The four distinct waveguides 28 are each UHF fed by a distinct UHF power source 30.

Up to now we presented and discussed generating the plasma by means of the plasma source according to the apparatus of the invention purely based on UHF electromagnetic power. Thereby low ion energies are reached, resulting in low damage rates of the atomic layer deposited.

In embodiments of the apparatus according to the invention, also in the embodiment as realized today, an ECR plasma is applied. By the ECR UHF plasma a very high degree of dissociation of the reactive gas and a very high reaction probability is reached. This significantly shortens the time span for reacting or oxidizing the yet deposited atomic layer with an oxidizing reactive gas, thereby keeping low ion energies.

This is realized by providing a permanent-magnet arrangement 36 along the periphery of the substrate carrier 3, and thus also along the waveguide arrangement 25.

Such permanent magnet arrangement 36 and the resulting magnet field H is shown in dash lines in all the FIGS. 2, 5 to 14: A plasma source being an ECR plasma source may be applied in combination with all embodiments discussed up to now and still to be discussed.

FIG. 15 shows schematically and simplified an ECR plasma source of an embodiment of the apparatus according to the invention. The permanent magnet arrangement 36 may be said a “horseshoe” magnet arrangement. An outer area of one magnetic polarity is aligned with the waveguide arrangement 25, whereas an inner area 36ᵢ of the other magnetic polarity extends remotely from the waveguide arrangement 25 adjacent to the coupling areas, in the example of FIG. 15, the sealingly covered -34- slits 32 in the hollow waveguide 28 and through the wall of vacuum recipient 1.

As may be seen from the embodiment according to FIG. 15, this structure allows to remove the magnet arrangement 36 as well as the waveguide arrangement 25—if not comprising separate waveguides 28—as respective, distinct parts for maintenance and/or replacement.

The plasma generated by the plasma source is ignited in one embodiment by means of a flashlight e.g. a Xe flashlight and extinguished by cutting off the respective UHF power sources 30 or switching off the respective operational connections between ongoingly operating UHF power sources 30 and the treatment space TS in the vacuum recipient 1.

As has been addressed in context with FIG. 1, the apparatus according to the invention is equipped with a controllable precursor gas inlet 13, connectable or connected to a precursor reservoir arrangement 17. The precursor reservoir arrangement 17, in today's practiced embodiment, contains TMA and thus aluminum as a metal. The precursor reservoir arrangement may comprise one or more than one precursor reservoir, then containing different precursors.

Further, the apparatus is equipped with a controllable reactive gas inlet 15 connectable or connected to a reactive gas tank arrangement 19. The reactive gas may e.g. be a gas containing at least one of the elements oxygen, nitrogen, carbon, hydrogen. In today's practiced embodiment the reactive gas is oxygen.

The reactive gas tank arrangement 19 may comprise one or more than one reactive gas tanks, then containing different reactive gases.

As schematically shown in FIG. 16 and in one embodiment of the apparatus according to the invention, the controllable precursor gas inlet 17 is located at the vacuum recipient 1 centrally with respect to the substrate carrier 3 and opposite the substrate 4 held on the substrate carrier 3. Thereby a homogeneous precursor gas distribution along the extended surface to be PEALD treated of substrate 4 is achieved. Although somehow less critical with respect to such distribution, the controlled reactive gas inlet 15 is located as centrally as possible aside the central precursor gas inlet 13.

Because the precursor gas and the reactive gas are not fed to the treatment space TS simultaneously for PEALD treatment, in one embodiment of the apparatus according to the invention, both, the precursor gas inlet 13 and the reactive gas inlet 15 are led centrally into the vacuum recipient 1. According to the schematic and simplified representation of FIG. 17, this is realized in that both gases are fed through common inlet 13/15 to the vacuum recipient 1 or, according to FIG. 18, in that the inlet 15 e.g. for the reactive gas is coaxial to the inlet 13 for the precursor gas.

The realization forms of the precursor gas inlet and of the reactive gas inlet may be combined with any embodiment of the apparatus according to the invention addressed up to now and still to be addressed.

With respect to high throughput of PEALD-treated substrates through the apparatus according to the invention, a governing factor is the volume of the treatment space TS.

In the apparatus according to the invention and as was addressed before, the substrate carrier 3 with a substrate 4 thereon in a treatment position defines in the vacuum recipient 1 a treatment space TS. In embodiments of the addressed apparatus there is valid for a ratio Φ of the volume of the treatment space TS and a top-view surface area of a surface of the substrate to be PEALD treated residing on the substrate carrier 1

8 cm≤Φ≤80 cm

preferably

10 cm≤Φ≤20 cm.

FIG. 19 shows, most simplified and schematically, the overall pumping/treatment structure of embodiments of the apparatus according to the invention, by which very small volumes of the treatment space TS and efficient pumping is achieved.

The substrate 4 and the wall of the vacuum recipient 1 are linked by a controlled pressure stage arrangement 40 looping around the substrate 4.

Whenever the controlled pressure stage arrangement 40 is controlled at a control input C40 to establish a high flow resistance up to a practically infinite flow resistance, a treatment space compartment TCS for the treatment space TS of small volume is established. The high flow resistance of the controlled pressure stage may be established by mechanical contact, e.g. of sealing surfaces or by non-contact e.g. by a labyrinth seal.

Whenever the controlled pressure stage 40 is controlled to establish a low flow resistance, efficient pumping of the vacuum recipient 1 including the treatment space TS is performed.

The treatment space compartment TCS may be dimensioned independently from the pumping compartment PC, which latter may be large so as to establish space for powerful pumping equipment and low flow resistance.

Whereas in the embodiments according to FIG. 19 the controlled pressure stage 40 interacts with the substrate carrier 1 or directly with the substrate 4, according to FIG. 20 the vacuum recipient 1 is separate in two compartments TSC and PC by a rigid traverse wall 42 in the vacuum recipient 1. By means of the controlled pressure stage 40a the flow resistance from the treatment space compartment TSC to the pumping compartment PC is controlled. The controlled pressure stage arrangement 40 needs not necessarily surround the substrate 4 or the workpiece carrier 3, and its operation does hardly influence mechanically the substrate as by contacting vibration.

The pumping/treatment structure as exemplified in FIG. 19 or 20 may be combined with any embodiment addressed to now or still to be addressed.

FIGS. 21 to 25 show, most schematically and simplified, handler arrangements 7 (FIG. 1) which may be provided at embodiments of the apparatus according to the invention. According to FIG. 21 an input/output substrate handling opening 44 is provided, through which a substrate handler 46 loads an untreated substrate 4 into the vacuum recipient 1 and on the substrate carrier 3 and removes a treated substrate 4 from the substrate carrier 3 and the vacuum recipient 1. The substrate handler 46 operates bi-directionally.

According to FIG. 22 and as a difference to the embodiments according to FIG. 21, the substrate handler 46 loads a substrate 4 to be treated together with the substrate carrier 3 into the vacuum recipient 1 and removes the treated substrate together with the substrate carrier 3 from the vacuum recipient 1, both through the substrate handling opening 44. Here too, the substrate handler 46 operates bi-directionally.

According to FIGS. 23 and 24 an input handling opening 44ᵢ and an output handling opening 44ₒ are provided in the vacuum recipient 1. An input substrate handler 46ᵢ loads an untreated substrate 4—according to FIG. 23 without substrate carrier 3, according to FIG. 24 with the substrate carrier 3—into the vacuum recipient 1, whereas an output substrate handler 46ₒ removes the treated substrate—according to FIG. 23 without substrate carrier 3, according to FIG. 24 with the workpiece carrier 3—from the vacuum recipient 1. The substrate handlers 46ᵢ and 46ₒ operate uni-directionally.

All handling openings 44, 44ᵢ, 44ₒ may be equipped with load locks (not shown).

The loading/unloading positions of the substrate 4 in the vacuum recipient 1 may be different from the PEALD treatment position of the substrate 4 in the vacuum recipient 1. This prevails for all embodiments of FIGS. 21 to 24.

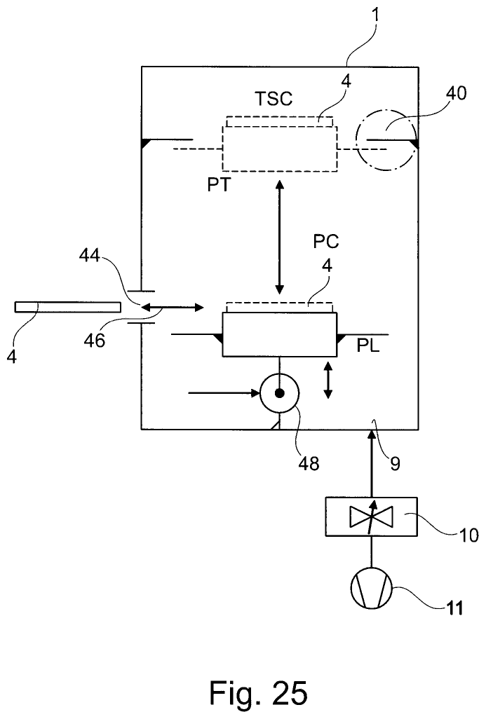

FIG. 25 shows, as an example, the embodiment according to FIG. 21, at which the loading/unloading position of the substrate 4 is different from the PEALD treatment position of the substrate 4. By means of a controlled drive 48 the substrate carrier 3 with the substrate 4 is moved from a loading/unloading position PL to a treatment position PT and vice versa. The driven movement of the substrate carrier 3 relative to the vacuum recipient 1 may thereby be exploited to establish, at the controlled pressure stage arrangement 40 (see FIG. 19) high gas flow resistance in the treatment position PT and low flow resistance as soon as the substrate carrier 3 leaves the treatment position PT. In the treatment position PT, a treatment space compartment TSC is established.

Please note, that the input substrate handler 46ᵢ and the output substrate handler 46ₒ may be realized commonly by a conveyer (not shown), e.g. by a disk—or ring-shaped conveyer, by a drum conveyer etc., by which conveyer untreated substrates are conveyed into the vacuum recipient 1 and PEALD-treated substrates are removed from the vacuum recipient 1.

It is again emphasized, that the embodiments of handler arrangements according to FIGS. 21 to 25 may be combined with all embodiments as addressed to now, and still to be addressed.

FIG. 26 shows schematically and simplified an embodiment of an apparatus according to the invention, combining embodiments as were addressed.

The vacuum recipient 1 has an input/output handling opening 44 in analogy to the embodiment of FIG. 21. A substrate handler 46 transports the substrate 4 on and from the substrate carrier 3. The waveguide arrangement 25, comprising rectangular cross-sectional waveguide 28, communicates with the treatment space TS in the vacuum recipient 1 by fused silica windows-sealed slits 32, according to the embodiment of FIG. 13. The plasma source is constructed as an ECR plasma source and comprises the permanent magnet arrangement 36 formed as a “horseshoe” magnet loop according to the embodiment of FIG. 15. The controllable precursor gas inlet 13 as well as the controllable reactive gas inlet 15 are located according to the embodiment of FIG. 16.

As shown in FIG. 27 the input/output handler 46 is realized as a fork. A substrate to be transported resides on two or more than two fork arms 52. By a horizontal, controlled movement -h- by means of a controlled linear fork drive (not shown) the fork arms 52 enter aligned grooves 54 in the surface 56 of the substrate carrier 3. The fork arms 52 thereby protrude from the grooves 54 at the surface 56 of the substrate carrier 3 so that a substrate 4 on the fork arms 52 does not touch the surface 56, as it is moved adjacent to the substrate carrier 3. The grooves 54 are deeper than the thickness of the fork arms 52. Thus, once the substrate is well aligned adjacent to the surface 56 of the substrate carrier 3, the fork is lowered -v- by a controlled vertical drive (not shown), and the substrate 4 is softly deposited on the surface 56 of the substrate carrier 3.

Once the substrate has been treated and is to be removed from the vacuum recipient 1, the fork arms 52 are entered in the grooves 54 without touching the substrate residing on the surface 56 and without touching the walls of the grooves 54. Then the fork arms 52 are moved upwards -v- in contact with the backside of the treated substrate, lift the substrate from the surface 56 and remove the substrate -h- from alignment with the substrate carrier 3 and out of the vacuum recipient 1.

Loading the substrate on the substrate carrier 3 and unloading the substrate from the substrate carrier 3 is performed in the position PL of the substrate carrier 3, in fact in analogy to the embodiment of FIG. 25. In FIG. 26 the PL-position of the substrate carrier 3 is drawn in solid lines. The substrate carrier 3 is moved between loading/unloading position PL and treatment position PT, drawn in dashed lines, by means of rods 58, controllably driven by a rod-drive (not shown). Once the substrate carrier 3 with the substrate to be PEALD-treated is in position PT, a frame 60 is lifted by means of rods 62, controllably driven by a drive (not shown) and establishes a high flow resistance between the treatment space TS, now a treatment space compartment TSC, and the pumping compartment PC. Making use of a frame as of frame 60 allows establishing the controlled pressure stage arrangement 40 as of embodiment of FIG. 19, so that the substrate is only loaded with minimal mechanical vibrations. This especially if the pressure stage arrangement to the substrate carrier side is realized in contactless manner, e.g. by a labyrinth seal.

FIG. 28 shows a flow diagram of the method according to the invention and as may be performed by the apparatus as was described to now.

A substrate to be PEALD-treated is loaded in a vacuum recipient (vacuum recipient 1). We name this step (0). If not already evacuated before the substrate is loaded, in step (0) the vacuum recipient is evacuated by pumping.

In step (1) a precursor gas is fed to the vacuum recipient (to the treatment space TS or to the treatment compartment TSC), and a precursor is adsorbed on the surface of the substrate.

In subsequent step (2) the vacuum recipient (including the treatment space or treatment compartment) is evacuated, removing excess precursor gas.

In step (3) a plasma is ignited in the vacuum recipient (ECR-UHF plasma PLA), and the deposited molecular layer resulting from step (2) is reacted with a reactive gas, plasma enhanced.

In step (4) the vacuum recipient is pumped, and excess reactive gas removed.

The steps (1) to (4) may be repeated n times (n≥1) so as to deposit multiple reacted molecular layers. Thereby in step (1) different precursors may be used and/or in step (3) different reactive gases, especially to form oxides, nitrides, carbides or metallic layers. In step (5) the treated substrate is removed from the vacuum recipient.

If steps (1) to (4) are repeated at least once after step (0) and before step (5), some of the steps (3) may be performed without igniting a plasma, or different plasmas may be applied for repeated steps (3).

Often a satisfying adsorption of a precursor, as of TMA, is only achieved on a surface, which is pretreated. Thus, and with an eye on FIG. 28 as addressed up to now, the substrate loaded in step (0) should provide for a pretreated, e.g. oxidized surface, which may have been applied before, in an upstream process to step (0).

In today's practiced method after step (0) a step (0a) is realized, in which the vacuum recipient is evacuated and the surface of the substrate to be PEALD-treated is reacted with a reactive gas. In FIG. 28 the step (0a) is shown in dash line. The step (0a) may be performed without plasma enhancement or with a plasma enhancement different from the plasma enhancements used for reacting the one or more than one deposited mono molecular layers or with a plasma equal to the plasma used for reacting at least one or more than one of the deposited monomolecular layers.

Further in step (0a) reacting may be performed with the same reactive gas as reacting one or more than one of the monomolecular layers, or with different reactive gas.

The time spans T₀ₐ, T₁, T₂, T₃, T₄ as indicated above and in FIG. 28 for the steps (0), (0a), (1), (2), (3), (4) have been evaluated for:
volume of treatment space compartment: 5 liters
substrate: 200 mm wafer
ECR-UHF plasma at 2.45 GHz
precursor gas: TMA
reactive gas: Oxygen.

The different aspects of the present invention are summarized and additionally disclosed as follows:

### ASPECTS

1. A plasma enhanced atomic layer deposition (PEALD) apparatus, comprising
   a vacuum recipient;
   at least one controllable pumping port from the vacuum recipient;
   at least one controllable plasma source communicating with the inner of said recipient;
   at least one controllable precursor gas inlet to the inner of said vacuum recipient;
   at least one controllable reactive gas inlet to the inner of said vacuum recipient;
   a substrate carrier in said recipient; wherein,
      said at least one plasma source is a UHF plasma source and is constructed to generate, distributed along a locus all around the periphery of said substrate carrier, a plasma in said vacuum recipient.
2. The PEALD apparatus of aspect 1, wherein said controllable plasma source is an ECR source.
3. The PEALD apparatus of aspect 1 or 2, wherein said plasma source comprises a multitude of UHF power sources each directly UHF-coupled to the inner space of said vacuum recipient via a respective coupling area.
4. The PEALD apparatus of aspect 3 said coupling area comprising a fused silica window sealing the inside of said vacuum recipient with respect to the UHF power source.
5. The PEALD apparatus of at least one of aspects 1 or 2, wherein said plasma source comprises a waveguide arrangement distributed all along said locus and comprising one or a multitude of coupling areas into said vacuum recipient, distributed all along said periphery of said substrate and further comprising at least one UHF power input.
6. The PEALD apparatus of one of aspects 1 to 5, wherein a substrate on said substrate carrier has an extended surface to be PEALD-coated exposed to a treatment space in said vacuum recipient, said locus being located around said treatment space.
7. The PEALD apparatus of one of aspects 5 or 6 said waveguide arrangement comprising more than one distinct waveguide segments, each comprising at least one UHF power input.
8. The PEALD apparatus of one of aspects 5 to 7 said waveguide arrangement being formed by at least one hollow waveguide and at least some of said coupling areas comprising a slit in said at least one hollow waveguide.
9. The PEALD apparatus of one of aspects 5 to 8, wherein said vacuum recipient has a center axis, and comprises at least two of said waveguide arrangements staggered in direction of said central axis.
10. The PEALD apparatus of aspect 9, wherein said at least one UHF power input of one of said at least two waveguide arrangements and said at least one power input of a further of said at least two waveguide arrangements are located mutually angularly displaced, seen in direction of said central axis.
11. The PEALD apparatus of one of aspects 5 to 10, wherein said substrate carrier defines a substrate plane, along which a substrate on said substrate carrier extends, and comprises at least two of said waveguide arrangements staggered in a direction perpendicular to said substrate plane.
12. The PEALD apparatus of aspect 11, wherein said at least one UHF power input of one of said at least two waveguide arrangements and said at least one power input of a further of said at least two waveguide arrangements are located mutually angularly displaced, seen in direction towards said substrate plane.
13. The PEALD apparatus of one of aspects 8 to 12, wherein said vacuum recipient has a center axis, at least some of said slits defining respective slit-opening surfaces, the central normals thereon pointing towards said central axis.
14. The PEALD apparatus of one of aspects 1 to 13, wherein said substrate carrier defines a substrate plane, along which a substrate on said substrate carrier extends, said vacuum recipient having a center axis perpendicular to said substrate plane.
15. The PEALD apparatus of at least one of aspects 8 to 14, wherein said substrate carrier defines a substrate plane, along which a substrate on said substrate carrier extends, at least some of said slits defining respective slit-opening surfaces, the respective central normals thereon being parallel to said substrate plane.
16. The PEALD apparatus of at least one of aspects 8 to 15, wherein said vacuum recipient has a center axis, the cross-sectional areas of hollow waveguides of said waveguide arrangement have symmetry planes or a common symmetry plane, perpendicular to said center axis, said at least one slit or at least some of more than one of said slits are offset from said symmetry planes or from said common symmetry plane.
17. The PEALD apparatus of aspect 16, wherein some of said slits are offset from said respective symmetry plane or from said common symmetry plane to one side, others of said slits to the other side.
18. The PEALD apparatus of aspect 17, wherein said slits are alternatingly offset to one and to the other side of the respective symmetry planes or of the common symmetry plane.
19. The PEALD apparatus of one of aspect 5 to 18 said waveguide arrangement comprising or consisting of hollow waveguides having a rectangular inside cross-section.
20. The PEALD apparatus of one of aspect 5 to 19, wherein said waveguide arrangement comprises or consists of hollow waveguides, the interior of said hollow waveguides being vacuum-sealed with respect to the interior of said vacuum recipient.
21. The PEALD apparatus of one of aspect 8 to 20, wherein said slits are vacuum-sealed with respect to the interior of said vacuum recipient.
22. The PEALD apparatus according to one of aspects 8 to 21, wherein said slits are vacuum-sealed with respect to the interior of said vacuum recipient by fused silica windows.
23. The PEALD apparatus of one of aspect 1 to 22 said UHF plasma source being a 2.45 GHz plasma source.
24. The PEALD apparatus of one of aspect 5 to 23, wherein said waveguide arrangement comprises or consists of linearly extending waveguide sections.
25. The PEALD apparatus of one of aspects 5 to 24 wherein said waveguide arrangement is located outside said vacuum recipient and communicates via coupling areas through the wall of said vacuum recipient with the inside of said vacuum recipient.
26. The PEALD apparatus of one of aspects 1 to 25, wherein said substrate carrier defines a substrate plane, along which a substrate on said substrate carrier extends, said locus extending along a plane parallel to said substrate plane.
27. The PEALD apparatus of one of aspects 5 to 26, wherein said waveguide arrangement is removable from said vacuum recipient as one distinct part.
28. The PEALD apparatus of one of aspects 2 to 27 said ECR plasma source comprising a permanent-magnet arrangement distributed all along said locus.
29. The PEALD apparatus of one of aspects 5 to 28 wherein said controllable plasma source is an Electron Cyclotron Resonance (ECR) source and comprises a permanent magnet arrangement adjacent to and along said waveguide arrangement.
30. The PEALD apparatus of aspect 29, wherein said waveguide arrangement consists or comprises of at least one hollow waveguide, said permanent-magnet arrangement comprising an outer pole area of one magnetic polarity and an inner pole area of the other magnetic polarity, said outer area extending aligned with the hollow inner space of said at least one hollow waveguide, the inner area extending remote from said waveguide arrangement and adjacent to said coupling areas.
31. The PEALD apparatus of one of aspects 1 to 30 comprising a plasma ignitor arrangement comprising an ignitor flashlight.
32. The PEALD apparatus of one of aspects 28 to 31, wherein said magnet arrangement is removable from said vacuum recipient as one distinct part.
33. The PEALD apparatus of one of aspects 1 to 32 comprising at least one precursor reservoir containing a precursor comprising a metal and operationally connected to said at least one controllable precursor gas inlet.
34. The PEALD apparatus of aspect 31, said metal being aluminum.
35. The PEALD apparatus of one of aspects 1 to 34 comprising at least one reactive gas tank containing a reactive gas and operationally connected to said at least one controllable reactive gas inlet.
36. The PEALD apparatus of aspect 35, said reactive gas tank containing at least one of the elements oxygen, nitrogen, carbon, hydrogen.
37. The PEALD apparatus of one of aspects 1 to 36 said at least one precursor gas inlet discharging centrally with respect to a substrate on said substrate carrier in a treatment position and towards said substrate.
38. The PEALD apparatus of one of aspects 1 to 37, wherein said at least one controllable precursor gas inlet and said at least one controllable reactive gas inlet discharge both centrally with respect to a substrate on said substrate carrier in a treatment position and towards said substrate.
39. The PEALD apparatus of one of aspects 1 to 38, wherein said substrate carrier with a substrate thereon in a treatment position defines in said vacuum recipient a treatment space and wherein there is valid for a ratio Φ of the volume of said treatment space to a top-view surface area of a surface of said substrate to be PEALD treated on said substrate carrier:

8 cm≤Φ≤80 cm

preferably

10 cm≤Φ≤20 cm.
40. The PEALD apparatus of one of aspects 1 to 39, wherein a treatment compartment enclosing a treatment space in said vacuum recipient is separated by a controllable pressure stage from a pumping compartment which comprises said at least one controlled pumping port.
41. The PEALD apparatus of aspect 40, wherein said pressure stage is a gas seal.
42. The PEALD apparatus of aspect 40, wherein said pressure stage is a non-contact gas flow restriction.
43. The PEALD of one of aspects 1 to 42, wherein said substrate carrier is controllably movable between a loading/unloading position and a PEALD treatment position.
44. The PEALD apparatus of one of aspects 1 to 43 comprising a controllably movable substrate handler arrangement operationally coupled to said substrate carrier.
45. The PEALD apparatus of one of aspects 1 to 44 comprising at least one substrate handling opening in said vacuum recipient.
46. The PEALD apparatus of aspect 45 comprising a bidirectional substrate handler cooperating with said at least one substrate handling opening.
47. The PEALD apparatus of one of aspects 1 to 46 comprising at least two substrate handling openings in said vacuum recipient, an input substrate handler cooperating with one of said at least two substrate handler openings and an output substrate handler cooperating with the other of said at least two substrate handler openings.
48. The PEALD apparatus of aspect 47, wherein both said input substrate handler and said output substrate handler are commonly realized by a substrate conveyer.
49. The PEALD apparatus of one of aspects 1 to 48 comprising a timer unit operationally connected at least to a control valve arrangement to said at least one precursor gas inlet, to a control valve arrangement to said at least one reactive gas inlet, to said at least one plasma source and to said at least one controllable pumping port.
50. A method of manufacturing a substrate with a layer deposited thereon by PEALD comprising:
   (0) providing a substrate in a recipient; Evacuating the recipient;
   (1) feeding a precursor gas into said evacuated recipient and depositing by adsorption a molecular layer from a material in said precursor gas on said substrate;
   (2) pumping remaining precursor gas from said recipient;
   (3) igniting a plasma in said recipient and plasma enhanced reacting the deposited molecular layer on said substrate with a reactive gas,
   (4) pumping said recipient and
   (5) removing the substrate from said recipient.
51. The method of aspect 50 performed by means of an apparatus according to at least one of aspects 1 to 49.
52. The method of aspect 50 or 51, wherein steps (1) to (4) are repeated at least once after step (0) and before step (5).
53. The method of aspect 52, wherein said repeating of step (1) is performed by feeding different precursor gases during at least some of said repeated steps (1).
54. The method of one of aspects 52 or 53, wherein said repeating of step (3) is performed by feeding different reactive gases during at least some of said repeated steps (3).
55. The method of one of aspects 52 to 54, at least some of said repeated steps (3) being performed without igniting a plasma.
56. The method of one of aspects 50 to 55 comprising performing a step (0a) after said step (0) and before said step (1) in which step (0a) said recipient is evacuated and the surface of the substrate is reacted with a reactive gas.
57. The method of aspect 56, wherein a plasma is ignited in said step (0a).
58. The method of one of aspects 56 or 57, wherein said reactive gas in said step (0a) is different from the reactive gas in at least one step (3).
59. The method of one of aspects 56 to 58, wherein said reactive gas in said step (0a) and the reactive gas in at least one step (3) are equal.
60. The method of one of aspects 50 to 59, wherein said precursor gas in step (1) or in at least one of repeated steps (1) is TMA.
61. The method of one of aspects 50 to 60, wherein said reactive gas contains at least one of the elements oxygen, nitrogen, carbon, hydrogen.
62. The method of one of aspects 50 to 61, wherein said step (1) or at least one of repeated steps (1) is performed in a time span T1 for which there is valid:

0.5 sec.≤T₁≤2 sec,

preferably

T₁≅1 sec.
63. The method of one of aspects 50 to 62, wherein said step (2) or at least one of repeated steps (2) is performed in a time span T2 for which there is valid:

0.5 sec.≤T₂≤2 sec,

preferably

T₂≅1 sec.
64. The method of one of aspects 50 to 63, wherein said step (3) or at least one of repeated steps (3) is performed in a time span T3 for which there is valid:

0.5 sec.≤T₃≤2 sec.

preferably

T₃≅1 sec.
65. The method of one of aspects 50 to 64 wherein said step (4) or at least one of repeated steps (4) is performed in a time span T4 for which there is valid:

0.5 sec.≤T₄≤2 sec,

preferably

T₄≅1 sec.
66. The method of one of aspects 50 to 65 comprising performing a step (0a) after said step (0) and before said step (1), in which step (0a) the surface of said substrate is reacted with a reactive gas, said step (0a) being performed in a time span T0a for which there is valid:

0.5 sec.≤T₀ₐ≤2 sec,

preferably

T₀ₐ≅1 sec.
67. The method of one of aspects 50 to 66 comprising establishing a higher gas flow resistance from a treatment space to a pumping space between step (0) and step (1) and/or between step (2) and step (3) and establishing a lower gas flow resistance from said treatment space to said pumping space between step (1) and step (2) and/or between step (3) and step (4).
68. The method of one of aspects 50 to 67 comprising generating said plasma ignited in said step (3) distributed along a locus all around the periphery of said substrate.
69. A method of manufacturing a device comprising a substrate with a layer deposited thereon by PEALD by a method according to at least one of aspects 50 to 68.

Thereby especially the following aspects are today practiced:
I. A plasma enhanced atomic layer deposition (PEALD) apparatus, as has been explained especially in context with FIG. 9, comprising
a vacuum recipient;
at least one controllable pumping port from the vacuum recipient;
at least one controllable plasma source communicating with the inner of said recipient;
at least one controllable precursor gas inlet to the inner of said vacuum recipient;
at least one controllable reactive gas inlet to the inner of said vacuum recipient;
a substrate carrier in said recipient; wherein,
   said at least one plasma source is an Electron Cyclotron Resonance (ECR)-UHF plasma source and is constructed to generate, distributed along a locus all around the periphery of said substrate carrier, a plasma in said vacuum recipient, and wherein one plasma source per equal unit of the circumferential extent of said substrate carrier is directly coupled through a coupling area at a distinct position to the inner space of said vacuum recipient and comprising an ECR permanent-magnet arrangement distributed all-along said locus.
II. The apparatus of aspect I wherein said substrate carrier has a circumferential extent which is equal to said unit.
III. The apparatus of one of aspects I or II 1 wherein said unit is at least 40 cm or is at least 50 cm or is at least 60 cm or at least 100 cm.
VI. The apparatus of one of aspects I to III 1 wherein said substrate carrier defines a substrate plane, along which a substrate on said substrate carrier extends, said coupling area defining an opening surface, the respective central normal thereon being parallel to said substrate plane.
V. The apparatus of one of aspects I to IV, wherein said substrate carrier with a substrate thereon in a treatment position defines in said vacuum recipient a treatment space and wherein there is valid for a ratio Φ of the volume of said treatment space to a top-view surface area of a surface of said substrate to be PEALD treated on said substrate carrier:

8 cm≤Φ≤80 cm

preferably

10 cm≤Φ≤20 cm.
VI. The apparatus of one of aspects I to V, wherein a treatment compartment enclosing a treatment space in said vacuum recipient is separated by a controllable pressure stage from a pumping compartment in said vacuum recipient which comprises said at least one controlled pumping port.
VII. The apparatus of aspect VI wherein said pressure stage is a gas seal.
VIII. The apparatus of aspect VI wherein said pressure stage is a non-contact gas flow restriction.
IX. The apparatus of one of aspects I to VIII, wherein said substrate carrier is controllably movable between a loading/unloading position and a PEALD treatment position.
X. The apparatus of one of aspects I to IX said coupling area comprising a fused silica window sealing the inside of said vacuum recipient with respect to the UHF power source.
XI. The apparatus of one of aspects I to X, wherein a substrate on said substrate carrier has an extended surface to be PEALD-coated exposed to a treatment space in said vacuum recipient, said locus being located around said treatment space.
XII. The apparatus of one of aspects I to XI wherein said substrate carrier defines a substrate plane, along which a substrate on said substrate carrier extends, said vacuum recipient having a center axis perpendicular to said substrate plane.
XIII. The apparatus of one of aspects I to XII said UHF plasma source being a 2.45 GHz plasma source.
XIV. The apparatus of one of aspects I to XIII wherein said substrate carrier defines a substrate plane, along which a substrate on said substrate carrier extends, said locus extending along a plane parallel to said substrate plane.
XV. The apparatus of one of aspects I to XIV comprising a plasma ignitor arrangement comprising an ignitor flashlight.
XVI. The apparatus of one of aspects I to XV, wherein said magnet arrangement is removable from said vacuum recipient as one distinct part.
XVII. The apparatus of one of aspects I to XVI comprising at least one precursor reservoir containing a precursor comprising a metal and operationally connected to said at least one controllable precursor gas inlet.
XVIII. The apparatus of aspect XVII said metal being aluminum.
XIX. The apparatus of one of aspects I to XVIII comprising at least one reactive gas tank containing a reactive gas and operationally connected to said at least one controllable reactive gas inlet.
XX. The apparatus of aspect XIX said reactive gas tank containing at least one of the elements oxygen, nitrogen, carbon, hydrogen.
XXI. The apparatus of one of aspects I to XX said at least one precursor gas inlet discharging centrally with respect to a substrate on said substrate carrier in a treatment position and towards said substrate.
XXII. The apparatus of one of aspects I to XXI wherein said at least one controllable precursor gas inlet and said at least one controllable reactive gas inlet discharge both centrally with respect to a substrate on said substrate carrier in a treatment position and towards said substrate.
XXIII. The apparatus of one of aspects I to XXII comprising at least one substrate handling opening in said vacuum recipient.
XXIV. The apparatus of aspect XXIII comprising a bidirectional substrate handler cooperating with said at least one substrate handling opening.
XXV. The apparatus of aspect XXIII comprising at least two substrate handling openings in said vacuum recipient, an input substrate handler cooperating with one of said at least two substrate handler openings and an output substrate handler cooperating with the other of said at least two substrate handler openings.
XXVI. The apparatus of aspect XXV, wherein both said input substrate handler and said output substrate handler are commonly realized by a substrate conveyer.
XXVII. The apparatus of one of aspects I to XXVI comprising a timer unit operationally connected at least to a control valve arrangement for said at least one precursor gas inlet, to a control valve arrangement for said at least one reactive gas inlet, to said at least one plasma source and to said at least one controllable pumping port.
XXVIII. The apparatus of one of aspects I to XXVII wherein said coupling area is the output area of a horn antenna.
XXIX. A method of manufacturing a substrate with a layer deposited thereon by PEALD comprising:
   (0) providing a substrate on a substrate carrier in a recipient and evacuating the recipient;
   (1) feeding a precursor gas into said evacuated recipient and depositing by adsorption a molecular layer from a material in said precursor gas on said substrate;
   (2) pumping remaining precursor gas from said recipient;
   (3) igniting and maintaining a plasma in said recipient and plasma enhanced reacting the deposited molecular layer on said substrate with a reactive gas,
   (4) pumping said recipient and
   (5) removing the substrate from said recipient thereby generating said plasma ignited and maintained by an Electron Cyclotron Resonance (ECR)-UHF plasma source constructed to generate, distributed along a locus all around the periphery of said substrate carrier, a plasma in said vacuum recipient, and by providing one plasma source per equal unit of the circumferential extent of said substrate carrier and by directly coupling said one plasma source through a coupling area at a distinct position to the inner space of said vacuum recipient and by generating an ECR-magnetic field all-along said locus.
XXX. The method of aspect XXIX performed by means of an apparatus according to at least one of aspects I to XXVIII.
XXXI. The method of aspect XXIX or XXX wherein steps (1) to (3) are repeated at least once after step (0) and before step (5).
XXXII. The method of aspect XXXI wherein said repeating of step (1) is performed by feeding different precursor gases during at least some of said repeated steps (1).
XXXIII. The method of one of aspect XXXI or XXXII, wherein said repeating of step (3) is performed by feeding different reactive gases during at least some of said repeated steps (3).
XXXIV. The method of one of aspects XXXI to XXXIII least some of said repeated steps (3) being performed without igniting a plasma.
XXXV. The method of one of aspects XXIX to XXXIV comprising performing a step (0a) after said step (0) and before said step (1) in which step (0a) said recipient is evacuated and the surface of the substrate is reacted with a reactive gas.
XXXVI. The method of aspect XXXV wherein a plasma is ignited in said step (0a).
XXXVII. The method of one of aspects XXXV or XXXVI wherein said reactive gas in said step (0a) is different from the reactive gas in at least one step (3).
XXXVIII. The method of one of aspects XXXV to XXXVII wherein said reactive gas in said step (0a) and the reactive gas in at least one step (3) are equal.
XXXIX. The method of one of aspects XXIX to XXXVIII said precursor gas in step (1) or in at least one of repeated steps (1) is TMA.
XL. The method of one of aspects XXIX to XXXIX wherein said reactive gas contains at least one of the elements oxygen, nitrogen, carbon, hydrogen.
XLI. The method of one of aspects XIX to XL, wherein said step (1) or at least one of repeated steps (1) is performed in a time span T1 for which there is valid:

0.5 sec.≤T₁≤2 sec,

or

T₁≅1 sec.
XLII. The method of one of aspects XIX to XLI, wherein said step (2) or at least one of repeated steps (2) is performed in a time span T2 for which there is valid:

0.5 sec.≤T₂≤2 sec,

or

T₂≅1 sec.
XLIII. The method of one of aspects XIX to XLII wherein said step (3) or at least one of repeated steps (3) is performed in a time span T3 for which there is valid:

0.5 sec.≤T₃≤2 sec.

or

T₃≅1 sec.
XLIV. The method of one of aspects XIX to XLIII wherein said step (4) or at least one of repeated steps (4) is performed in a time span T4 for which there is valid:

0.5 sec.≤T4≤2 sec,

or

T₄≅1 sec.
XLV. The method of one of aspects XIX to XLIV comprising performing a step (0a) after said step (0) and before said step (1), in which step (0a) the surface of said substrate is reacted with a reactive gas, said step (0a) being performed in a time span T0a for which there is valid:

0.5 sec.≤T₀ₐ≤2 sec,

or

T₀ₐ≅1 sec.
XLVI. The method of one of aspects XIX to XLV comprising establishing a higher gas flow resistance from a treatment space in said recipient to a pumping space in said recipient between step (0) and step (1) and/or between step (2) and step (3) and establishing a lower gas flow resistance from said treatment space to said pumping space between step (1) and step (2) and/or between step (3) and step (4).
XLVII. A method of manufacturing a device comprising a substrate with a layer deposited thereon by PEALD by a method according to at least one of aspects XIX to XLVI.

| Reference-Nr. | |
|---|---|
| 1 | Vacuum recipient |
| 3 | Substrate carrier |
| 4 | substrate |
| 4o | Surface to be PEALD treated |
| TS | Treatment space |
| TSC | Treatment space compartment |
| PC | Pumping compartment |
| 5 | UHF plasma source |
| PLA | Plasma |
| 7 | Substrate handler arrangement |
| 9 | Controllable pumping port |
| 10 | valve arrangement |
| 11 | pumping arrangement |
| 13 | controllable precursor gas inlet |
| 14 | Valve arrangement |
| 15 | controllable reactive gas inlet |
| 16 | Valve arrangement |
| 17 | precursor reservoir arrangement |
| 19 | reactive gas tank arrangement |
| W | Possible substrate rotation |
| L | locus |
| 21 | Timer unit |
| 25 | Waveguide arrangement |
| 26 | feeding areas |
| 27 | coupling area |
| 28 | waveguide |
| 30 | UHF power source |
| 32 | slit |
| 34 | window |
| 36 | Permanent Magnet arrangement |
| 36o | One polarity area (outer) |
| 36i | Other polarity area (inner) |
| 40, 40a | Controlled pressure stage arrangement |
| 44, 44o, 44i | Substrate handling opening |
| 46, 46o, 46i | Substrate handler |
| 48 | controlled drive |
| 52 | Fork arm |
| 54 | grooves |
| 56 | surface |
| 58 | rods |
| 62 | rods |
| 60 | frame |
| A | axis |
| Es | Plane along which substrate resides on |
| | substrate carrier 3 |
| Esym | Symmetry plane of hollow waveguide 28 |
| H | Magnetic field |
| PL | Loading-, unloading position |
| PT | PEALD treatment position |

What is claimed is:

1-46. (canceled)

47. A plasma enhanced atomic layer deposition (PEALD) apparatus, comprising
a vacuum recipient;
at least one controllable pumping port from the vacuum recipient;
at least one controllable plasma source communicating with the inner of said recipient;
at least one controllable precursor gas inlet to the inner of said vacuum recipient;
at least one controllable reactive gas inlet to the inner of said vacuum recipient;
a substrate carrier in said recipient, wherein said at least one plasma source is an Electron Cyclotron Resonance (ECR)-UHF plasma source and comprises an UHF power source directly coupled through a coupling area at a distinct position to the inner space of said vacuum recipient, and
said at least one plasma source being constructed to generate, distributed along a locus all around the periphery of said substrate carrier, a plasma in said vacuum recipient; and
one UHF power source per equal unit of at least 40 cm of the circumferential extent of said substrate carrier being directly coupled through said coupling area at said distinct position to said inner space of said vacuum recipient, wherein
said plasma source comprising an ECR permanent-magnet arrangement distributed all-along said locus.

48. The apparatus of claim 47 wherein said substrate carrier has a circumferential extent which is equal to said unit.

49. The apparatus of claim 47 wherein said unit is at least 50 cm or is at least 60 cm or at least 100 cm.

50. The apparatus of claim 47 wherein said substrate carrier defines a substrate plane, along which a substrate on said substrate carrier extends, said coupling area defining an opening surface, the respective central normal thereon being parallel to said substrate plane.

51. The apparatus of claim 47, wherein said substrate carrier with a substrate thereon in a treatment position defines in said vacuum recipient a treatment space and wherein there is valid for a ratio Φ of the volume of said treatment space to a top-view surface area of a surface of said substrate to be PEALD treated on said substrate carrier:
8 cm≤Φ≤80 cm
preferably
10 cm≤Φ≤20 cm.

52. The apparatus of claim 47, wherein a treatment compartment enclosing a treatment space in said vacuum recipient is separated by a controllable pressure stage from a pumping compartment in said vacuum recipient which comprises said at least one controlled pumping port.

53. The apparatus of claim 52 wherein said pressure stage is a gas seal.

54. The apparatus of claim 52 wherein said pressure stage is a non-contact gas flow restriction.

55. The apparatus of claim 47, wherein said substrate carrier is controllably movable between a loading/unloading position and a PEALD treatment position.

56. The apparatus of claim 47 said coupling area comprising a fused silica window sealing the inside of said vacuum recipient with respect to the UHF power source.

57. The apparatus of claim 47, wherein a substrate on said substrate carrier has an extended surface to be PEALD-coated exposed to a treatment space in said vacuum recipient, said locus being located around said treatment space.

58. The apparatus of claim 47 wherein said substrate carrier defines a substrate plane, along which a substrate on said substrate carrier extends, said vacuum recipient having a center axis perpendicular to said substrate plane.

59. The apparatus of claim 47 said UHF plasma source being a 2.45 GHz plasma source.

60. The apparatus of claim 47 wherein said substrate carrier defines a substrate plane, along which a substrate on said substrate carrier extends, said locus extending along a plane parallel to said substrate plane.

61. The apparatus of claim 47 comprising a plasma ignitor arrangement comprising an ignitor flashlight.

62. The apparatus of claim 47, wherein said magnet arrangement is removable from said vacuum recipient as one distinct part.

63. The apparatus of claim 47 comprising at least one precursor reservoir containing a precursor comprising a metal and operationally connected to said at least one controllable precursor gas inlet.

64. The apparatus of claim 63, said metal being aluminum.

65. The apparatus of claim 47 comprising at least one reactive gas tank containing a reactive gas and operationally connected to said at least one controllable reactive gas inlet.

66. The apparatus of claim 65 said reactive gas tank containing at least one of the elements oxygen, nitrogen, carbon, or hydrogen.

67. The apparatus of claim 47 said at least one precursor gas inlet discharging centrally with respect to a substrate on said substrate carrier in a treatment position and towards said substrate.

68. The apparatus of claim 47 wherein said at least one controllable precursor gas inlet and said at least one controllable reactive gas inlet discharge both centrally with respect to a substrate on said substrate carrier in a treatment position and towards said substrate.

69. The apparatus of claim 47 comprising at least one substrate handling opening in said vacuum recipient.

70. The apparatus of claim 69 comprising a bidirectional substrate handler cooperating with said at least one substrate handling opening.

71. The apparatus of claim 69 comprising at least two substrate handling openings in said vacuum recipient, an input substrate handler cooperating with one of said at least two substrate handler openings and an output substrate handler cooperating with the other of said at least two substrate handler openings.

72. The PEALD apparatus of aspect 71, wherein both said input substrate handler and said output substrate handler are commonly realized by a substrate conveyer.

73. The apparatus of claim 47 comprising a timer unit operationally connected at least to a control valve arrangement for said at least one precursor gas inlet, to a control valve arrangement for said at least one reactive gas inlet, to said at least one plasma source and to said at least one controllable pumping port.

74. A method of manufacturing a substrate with a layer deposited thereon by PEALD comprising:
(0) providing a substrate on a substrate carrier in a recipient; Evacuating the recipient;
(1) feeding a precursor gas into said evacuated recipient and depositing by adsorption a molecular layer from a material in said precursor gas on said substrate;
(2) pumping remaining precursor gas from said recipient;
(3) igniting and maintaining a plasma in said recipient and plasma enhanced reacting the deposited molecular layer on said substrate with a reactive gas;
(4) pumping said recipient; and
(5) removing the substrate from said recipient thereby generating said plasma ignited and maintained by an Electron Cyclotron Resonance (ECR)-UHF plasma source constructed to generate, distributed along a locus all around the periphery of said substrate carrier, a plasma in said vacuum recipient, and by providing one UHF power source per equal unit of at least 40 cm of the circumferential extent of said substrate carrier and by directly coupling said one UHF power source through a coupling area at a distinct position to the inner space of said vacuum recipient and by generating an ECR magnetic field all-along said locus.

75. The method of claim 74 performed by a plasma enhanced atomic layer deposition (PEALD) apparatus, comprising
a vacuum recipient;
at least one controllable pumping port from the vacuum recipient;
at least one controllable plasma source communicating with the inner of said recipient;
at least one controllable precursor gas inlet to the inner of said vacuum recipient;
at least one controllable reactive gas inlet to the inner of said vacuum recipient;
a substrate carrier in said recipient, wherein said at least one plasma source is an Electron Cyclotron Resonance (ECR)-UHF plasma source and comprises an UHF power source directly coupled through a coupling area at a distinct position to the inner space of said vacuum recipient, and
said at least one plasma source being constructed to generate, distributed along a locus all around the periphery of said substrate carrier, a plasma in said vacuum recipient; and
one UHF power source per equal unit of at least 40 cm of the circumferential extent of said substrate carrier being directly coupled through said coupling area at said distinct position to said inner space of said vacuum recipient, wherein
said plasma source comprising an ECR permanent-magnet arrangement distributed all-along said locus.

76. The method of claim 74 wherein steps (1) to (4) are repeated at least once after step (0) and before step (5).

77. The method of claim 76, wherein said repeating of step (1) is performed by feeding different precursor gases during at least some of said repeated steps (1).

78. The method of claim 76, wherein said repeating of step (3) is performed by feeding different reactive gases during at least some of said repeated steps (3).

79. The method of claim 76, at least some of said repeated steps (3) being performed without igniting a plasma.

80. The method of claim 74 comprising performing a step (0a) after said step (0) and before said step (1) in which step (0a) said recipient is evacuated and the surface of the substrate is reacted with a reactive gas.

81. The method of claim 80, wherein a plasma is ignited in said step (0a).

82. The method of claim 80, wherein said reactive gas in said step (0a) is different from the reactive gas in at least one step (3).

83. The method of claim 80, wherein said reactive gas in said step (0a) and the reactive gas in at least one step (3) are equal.

84. The method of claim 74, wherein said precursor gas in step (1) or in at least one of repeated steps (1) is TMA.

85. The method of claim 74, wherein said reactive gas contains at least one of the elements oxygen, nitrogen, carbon, or hydrogen.

86. The method of claim 74, wherein said step (1) or at least one of repeated steps (1) is performed in a time span T1 for which there is valid:
0.5 sec.≤T₁≤2 sec,
or
T₁≅1 sec.

87. The method of claim 74, wherein said step (2) or at least one of repeated steps (2) is performed in a time span T2 for which there is valid:
0.5 sec.≤T₂≤2 sec,
or
T₂≅1 sec.

88. The method of claim 74, wherein said step (3) or at least one of repeated steps (3) is performed in a time span T3 for which there is valid:
0.5 sec.≤T₃≤2 sec.
or
T₃≅1 sec.

89. The method of claim 74 wherein said step (4) or at least one of repeated steps (4) is performed in a time span T4 for which there is valid:
0.5 sec.≤T₄≤2 sec,
or
T₄≅1 sec.

90. The method of claim 74 comprising performing a step (0a) after said step (0) and before said step (1), in which step (0a) the surface of said substrate is reacted with a reactive gas, said step (0a) being performed in a time span T0a for which there is valid:
0.5 sec.≤T₀ₐ≤2 sec,
or
T₀ₐ≅1 sec.

91. The method of claim 74 comprising establishing a higher gas flow resistance from a treatment space in said recipient to a pumping space in said recipient between step (0) and step (1) and/or between step (2) and step (3) and establishing a lower gas flow resistance from said treatment space to said pumping space between step (1) and step (2) and/or between step (3) and step (4).

92. A method of manufacturing a device comprising a substrate with a layer deposited thereon by PEALD by a method according to claim 74.
